(19) United States
(12) Patent Application Publication
(10) Pub. No.: US 2025/0252044 A1
(43) Pub. Date: Aug. 7, 2025

(54) MEMORY SYSTEM AND METHOD OF CONTROLLING NON-VOLATILE MEMORY

(71) Applicant: Kioxia Corporation, Tokyo (JP)

(72) Inventors: Masahiro KIYOOKA, Yokohama Kanagawa (JP); Yoshihisa KOJIMA, Kawasaki Kanagawa (JP); Dongxiao YU, Tokyo (JP); Toshikatsu HIDA, Yokohama Kanagawa (JP); Riki SUZUKI, Yokohama Kanagawa (JP); Suguru NISHIKAWA, Tokyo (JP)

(73) Assignee: Kioxia Corporation, Tokyo (JP)

(21) Appl. No.: 18/882,227

(22) Filed: Sep. 11, 2024

(30) Foreign Application Priority Data
Feb. 5, 2024 (JP) 2024-015719

(51) Int. Cl. G06F 12/02; G11C 29/12; G11C 29/42

(52) U.S. Cl. CPC G06F 12/0246; G11C 29/12005; G11C 29/42

(57) ABSTRACT

According to one embodiment, a memory system comprises a non-volatile memory that includes a plurality of memory cells and a memory controller. The memory controller is configured to set a first read voltage based on a first shift value, acquire hard bit data by a first read operation using the first read voltage, set a second read voltage based on a second shift value, acquire soft bit data by a second read operation using the second read voltage, execute first error correction by using the hard bit data and the soft bit data, calculate a first log likelihood ratio (LLR) by using at least a result of the first error correction that has failed, and correct at least one of the first shift value and the second shift value based on the first LLR.

### CROSS-REFERENCE TO RELATED APPLICATION

This application is based upon and claims the benefit of priority from Japanese Patent Application No. 2024-015719, filed Feb. 5, 2024, the entire contents of which are incorporated herein by reference.

### FIELD

Embodiments described herein relate generally to a memory system and a method of controlling a non-volatile memory.

### BACKGROUND

As a memory system, there is known a solid state drive (SSD) on which a non-volatile memory such as a NAND flash memory is mounted.

### BRIEF DESCRIPTION OF DRAWINGS

FIG. 1 is a block diagram illustrating an example of an overall configuration of an information processing system including a memory system according to a first embodiment.

FIG. 2 is a block diagram illustrating an example of a configuration of an error check and correction (ECC) circuit included in the memory system according to the first embodiment.

FIG. 3 is a block diagram illustrating an example of a basic configuration of a NAND flash memory included in the memory system according to the first embodiment.

FIG. 4 is a circuit diagram illustrating an example of a circuit configuration of a memory cell array included in the memory system according to the first embodiment.

FIG. 5 is a diagram illustrating threshold voltage distributions and data assignment in a case where memory cells included in the memory system according to the first embodiment are triple level cells (TLCs).

FIG. 6 is a diagram illustrating an example of a relationship among threshold voltage distributions, an HB read voltage and SB read voltages, an LLR table, and a channel matrix in the memory system according to the first embodiment.

FIG. 7 is a diagram illustrating an example of a shift value correction process of a read voltage in the memory system according to the first embodiment.

FIG. 8 is a flowchart illustrating an example of an overall procedure of a read operation in the memory system according to the first embodiment.

FIG. 9 is a flowchart illustrating an example of the overall procedure of the read operation in the memory system according to the first embodiment.

FIG. 10 is a diagram illustrating an example of a shift value correction process of a read voltage in the memory system according to a first modification of the first embodiment.

FIG. 11 is a flowchart illustrating an example of a procedure of an SB read and SB decoding in the memory system according to the first modification of the first embodiment.

FIG. 12 is a diagram illustrating an example of a shift value correction process of a read voltage in the memory system according to a second modification of the first embodiment.

FIG. 13 is a flowchart illustrating an example of a procedure of an SB read and SB decoding in the memory system according to the second modification of the first embodiment.

FIG. 14 is a diagram illustrating an example of a shift value correction process in a case where an interval between read voltages is widened in a memory system according to a second embodiment.

FIG. 15 is a diagram illustrating an example of a shift value correction process in a case where an interval between read voltages is narrowed in the memory system according to the second embodiment.

FIG. 16 is a flowchart illustrating an example of a procedure of an SB read and SB decoding in the memory system according to the second embodiment.

FIG. 17 is a block diagram illustrating an example of an overall configuration of an information processing system including a memory system according to a third embodiment.

FIG. 18 is a flowchart illustrating an example of a procedure of an SB read and SB decoding in the memory system according to the third embodiment.

FIG. 19 is a flowchart illustrating an example of a procedure of an SB read and SB decoding in the memory system according to a modification of the third embodiment.

### DETAILED DESCRIPTION

In general, according to one embodiment, a memory system comprises a non-volatile memory and a memory controller. The non-volatile memory includes a plurality of memory cells each configured to store data according to a threshold voltage. The memory controller is configured to set a first read voltage based on a first shift value, acquire hard bit data from the plurality of memory cells by a first read operation using the first read voltage, set a second read voltage based on a second shift value, acquire soft bit data from the plurality of memory cells by a second read operation using the second read voltage, execute first error correction on data read from the plurality of memory cells by using the hard bit data and the soft bit data, calculate a first log likelihood ratio (LLR) by using at least a result of the first error correction that has failed when the first error correction has failed, and correct at least one of the first shift value and the second shift value based on the first LLR.

Embodiments will be described below with reference to the drawings. The drawings are schematic. In the following descriptions, the constituent elements with approximately identical functions and configurations will be given identical reference signs. Numbers after the characters constituting the reference numerals are used to distinguish elements having similar configurations.

### 1. First Embodiment

A memory system according to a first embodiment will be described.

### 1.1 Configuration

### 1.1.1 Configuration of Information Processing System

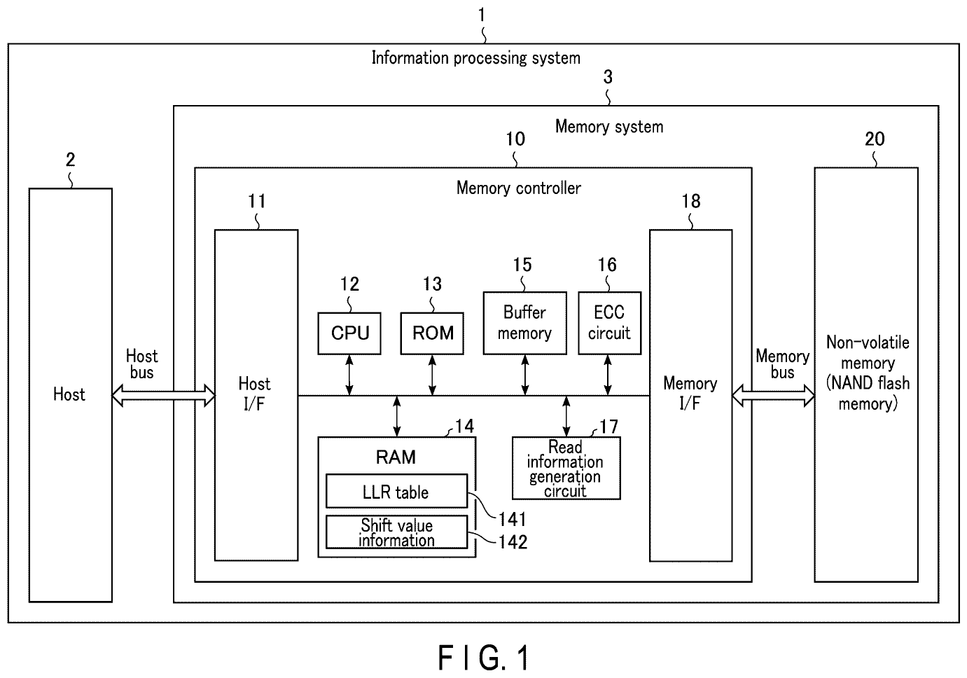

First, an example of a configuration of an information processing system 1 including a memory system 3 will be described with reference to FIG. 1. FIG. 1 is a block diagram illustrating an example of an overall configuration of the information processing system 1 including the memory system 3.

As illustrated in FIG. 1, the information processing system 1 includes a host 2 and the memory system 3. A plurality of memory systems 3 may be coupled to the host 2.

The host 2 is an information processing device (computing device) that accesses the memory system 3. The host 2 controls the memory system 3. More specifically, the host 2 requests (instructs) the memory system 3 to perform a write operation or a read operation of data (hereinafter, referred to as user data), for example.

The memory system 3 is a solid state drive (SSD), a universal flash storage (UFS) device, a universal serial bus (USB) memory, a multi-media card (MMC), or an SD card (trademark), for example. The memory system 3 is coupled to the host 2 via a host bus. The type of the host bus depends on an application applied to the memory system 3. If the memory system 3 is an SSD, the host bus conforms to the peripheral component interconnect express (PCIe) (trademark) standard, for example. The memory system 3 executes processing based on a request signal received from the host 2 or a voluntary processing request.

### 1.1.2 Configuration of Memory System

Next, an example of a configuration of the memory system 3 will be described with reference to FIG. 1.

As illustrated in FIG. 1, the memory system 3 includes a memory controller 10 and a non-volatile memory 20. The non-volatile memory 20 is a NAND flash memory, for example. The non-volatile memory 20 may be a non-volatile storage medium other than a NAND flash memory. In the following description, the non-volatile memory 20 is a NAND flash memory. In the following description, the non-volatile memory 20 will also be referred to as a NAND flash memory 20.

The memory controller 10 is a system-on-a-chip (SoC), for example. The memory controller 10 may include a plurality of semiconductor chips. The memory controller 10 is coupled to the host 2 via the host bus. The memory controller 10 is also coupled to the NAND flash memory 20 via a memory bus. The memory controller 10 controls the NAND flash memory 20 based on a request signal received from the host 2 or a voluntary processing request. For example, in response to a request (instruction) from the host 2, the memory controller 10 instructs the NAND flash memory 20 to perform a read operation, a write operation, an erase operation, or the like. In addition, the memory controller 10 manages a memory space of the NAND flash memory 20.

The NAND flash memory 20 is a non-volatile storage medium. The NAND flash memory 20 includes a memory cell transistor (hereinafter, also referred to as memory cell) that stores data in a non-volatile manner. The NAND flash memory 20 stores data received from the memory controller 10 (hereinafter, also referred to as write data) in a non-volatile manner. The NAND flash memory 20 transmits data read from the memory cell (hereinafter, also referred to as read data) to the memory controller 10. The memory system 3 may include a plurality of NAND flash memories 20.

Next, an internal configuration of the memory controller 10 will be described. The memory controller 10 includes a host interface circuit (host I/F) 11, a central processing unit (CPU) 12, a read only memory (ROM) 13, a random access memory (RAN) 14, a buffer memory 15, an error check and correction (ECC) circuit 16, a read information generation circuit 17, and a memory interface circuit (memory I/F) 18. These circuits are coupled to each other by an internal bus in the memory controller 10. Each function of the memory controller 10 may be implemented by a dedicated circuit or may be implemented by the CPU 12 executing firmware.

The host interface circuit 11 is a circuit coupled to the host 2 via the host bus. The host interface circuit 11 performs communication between the host 2 and the memory controller 10. The host interface circuit 11 transmits a request received from the host 2 to the CPU 12. The host interface circuit 11 transmits user data received from the host 2 to the buffer memory 15. The host interface circuit 11 also transmits user data stored in the buffer memory 15 to the host 2 in response to an instruction from the CPU 12.

The CPU 12 is a processor. The CPU 12 controls the entire operation of the memory controller 10. For example, the CPU 12 instructs the NAND flash memory 20 to perform a write operation, a read operation, an erase operation, and the like in response to a request received from the host 2.

The ROM 13 is a non-volatile memory. For example, the ROM 13 is an electrically erasable programmable read-only memory (EEPROM) (trademark). The ROM 13 is a non-transitory storage medium that stores firmware, programs, and the like. For example, the CPU 12 loads firmware from the ROM 13 to the RAM 14 and executes it.

The RAM 14 is a volatile memory. The RAM 14 is a dynamic random access memory (DRAM), a static random access memory (SRAM), or the like. The RAM 14 is used as a work area of the CPU 12. In addition, the RAM 14 stores firmware for managing the NAND flash memory 20, various management tables, and the like. The RAM 14 stores a log likelihood ratio (LLR) table 141 and shift value information 142, for example.

The LLR table 141 is a table that associates data read from the NAND flash memory 20 with LLRs. The LLR table 141 is used for soft bit decoding to be described later. The LLR is information in which a probability that the data is “0” and a probability that the data is “1” are expressed in a logarithmic ratio. For example, the LLR has a positive value in a case where the probability that the data is “0” is higher than the probability that the data is “1”. In addition, the LLR has a negative value in a case where the probability that the data is “1” is higher than the probability that the data is “0”.

The shift value information 142 is information related to a shift value used to set a read voltage in a read operation (hereinafter, simply referred to as a read voltage). For example, when instructing the NAND flash memory 20 to perform the read operation, the CPU 12 transmits a command set (hereinafter, also referred to as Set Feature) of parameter setting related to the shift value and a command set of the read operation to the NAND flash memory 20. The command set of the read operation includes an execution command and an address of the read operation. The NAND flash memory 20 shifts a preset default read voltage based on the shift value. Note that, the shift value information 142 may be provided for each cell unit to be described later, for each word line, or for each block.

The buffer memory 15 is a volatile memory. The buffer memory 15 is a DRAM, an SRAM, or the like. The buffer memory 15 temporarily stores user data and the like.

The ECC circuit 16 is a circuit that executes an ECC process. The ECC process includes encoding and decoding of data. Hereinafter, data that is collectively processed when the ECC circuit 16 performs encoding and decoding will be referred to as an ECC frame.

The encoding is an operation of generating a code word based on data. The ECC circuit 16 encodes data to be written to the NAND flash memory 20. The data may be user data or system data of the memory system 3. In the following description, the user data will be taken as an example. Types of codes used for encoding include Bose-Chaudhuri-Hocquenghem (BCH) codes, Reed-Solomon (RS) codes, low-density parity-check (LDPC) codes, and the like. The ECC circuit 16 generates an error correction code (hereinafter, also referred to as parity) based on the user data. Then, the ECC circuit 16 adds the parity to the user data to generate a code word, that is, write data.

Decoding is an operation of performing error correction of data. The ECC circuit 16 decodes data read from the NAND flash memory 20. The decoding includes hard bit decoding and soft bit decoding. Hereinafter, the hard bit decoding will also be referred to as HB decoding. The soft bit decoding will also be referred to as SB decoding. The HB decoding is a decoding process using a set of hard decision values (hard bits) read from the NAND flash memory 20 (hereinafter, the set of hard bits is also referred to as HB data). The SB decoding is a decoding process using the HB data and a set of soft decision values (soft bits) read from the NAND flash memory 20 (hereinafter, the set of soft bits is also referred to as SB data). Details of the HB decoding and the SB decoding will be described later.

The read information generation circuit 17 is a circuit that generates the setting information of the read voltage in the read operation. For example, if the ECC circuit 16 has failed in the SB decoding, the read information generation circuit 17 according to the present embodiment corrects (generates) the shift value of the read voltage based on at least a result of the failure (hereinafter, also referred to as failure data). That is, if the ECC circuit 16 has failed the SB decoding, the read information generation circuit 17 changes the read voltage. The read information generation circuit 17 can update the shift value information 142 based on the corrected shift value.

The memory interface circuit 18 is a circuit that is coupled to the NAND flash memory 20 via the memory bus. The memory interface circuit 18 performs communication between the memory controller 10 and the NAND flash memory 20. The memory interface circuit 18 transmits and receives data and various signals to and from the NAND flash memory 20 under the control of the CPU 12.

### 1.1.3 Configuration of ECC Circuit

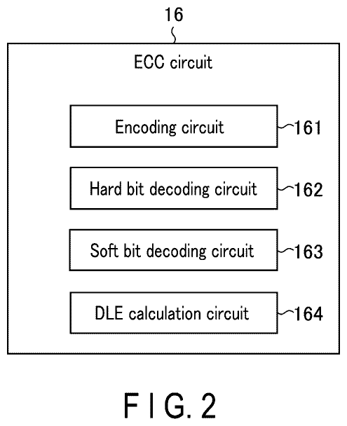

Next, an example of a configuration of the ECC circuit 16 will be described with reference to FIG. 2. FIG. 2 is a block diagram illustrating an example of a configuration of the ECC circuit 16.

As illustrated in FIG. 2, the ECC circuit 16 includes an encoding circuit 161, a hard bit decoding circuit 162, a soft bit decoding circuit 163, and a dynamic LLR estimation (DLE) calculation circuit 164.

The encoding circuit 161 is a circuit that encodes data (user data). The encoding circuit 161 generates a parity based on the data. The encoding circuit 161 adds parity to the data to generate write data (code word).

The hard bit decoding circuit 162 is a circuit that performs HB decoding of read data. The hard bit decoding circuit 162 executes the HB decoding using HB data.

The soft bit decoding circuit 163 is a circuit that performs SB decoding of read data. The soft bit decoding circuit 163 executes the SB decoding using HB data, SB data, and the LLR table 141. For example, the soft bit decoding circuit 163 executes the SB decoding if the hard bit decoding circuit 162 has failed in HB decoding.

The DLE calculation circuit 164 is a circuit that calculates DLE using a result of the SB decoding. The DLE is an LLR calculated using the result of the SB decoding. In the following description, the DLE calculated by using at least the result of failed SB decoding (hereinafter, also referred to as failure data) will be referred to as DLE1. The DLE calculated by using the result of successful SB decoding (hereinafter, also referred to as success data) will be referred to as DLE2. If the soft bit decoding circuit 163 has failed in the SB decoding, the DLE calculation circuit 164 according to the present embodiment calculates the DLE1 using the failure data. More specifically, the DLE calculation circuit 164 generates a channel matrix using the failure data. The channel matrix is information of a count value obtained by counting the number of zeros and ones in the data. The DLE calculation circuit 164 counts the number of zeros and ones for each section of the threshold voltage of the memory cell. The DLE calculation circuit 164 calculates the DLE1 using the channel matrix of the failure data.

### 1.1.4 Configuration of NAND Flash Memory

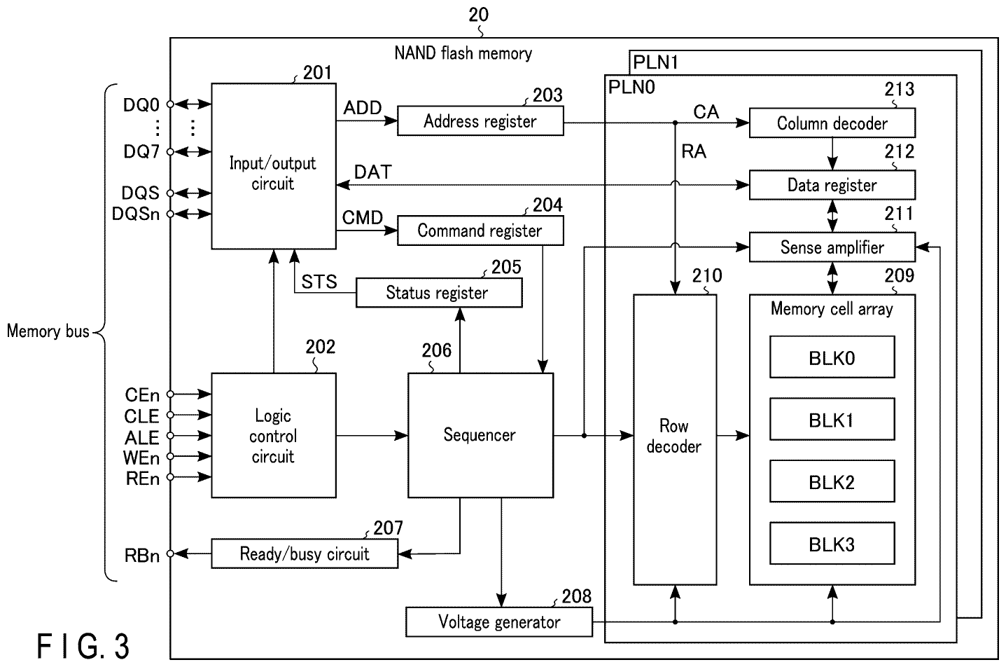

Next, an example of a configuration of the NAND flash memory 20 will be described with reference to FIG. 3. FIG. 3 is a block diagram illustrating an example of a basic configuration of the NAND flash memory 20. In the example illustrated in FIG. 3, some of the connections between the components are indicated by an arrow line. However, the connections between the components are not limited to the example illustrated in FIG. 3.

As illustrated in FIG. 3, the NAND flash memory 20 transmits and receives various control signals, signals DQ, and timing signals DQS and DQSn to and from the memory controller 10 (more specifically, the memory interface circuit 18) via the memory bus. The signal DQ is data DAT, an address ADD, or a command CMD, for example. The timing signals DQS and DQSn are timing signals used at the time of input and output of data DAT. The timing signal DQSn is an inverted signal of the timing signal DQS.

The NAND flash memory 20 receives various control signals from the memory controller 10 via the memory bus. For example, the NAND flash memory 20 receives a chip enable signal CEn, a command latch enable signal CLE, an address latch enable signal ALE, a write enable signal WEn, and a read enable signal REn. The chip enable signal CEn is a signal for enabling the NAND flash memory 20. The command latch enable signal CLE is a signal indicating that the signal DQ is a command CMD. The address latch enable signal ALE is a signal indicating that the signal DQ is an address ADD. The write enable signal WEn is a signal for taking the received signal DQ into the NAND flash memory 20 if the signal DQ is an address ADD or a command CMD. The read enable signal REn is a signal for the memory controller 10 to read data from the NAND flash memory 20.

The NAND flash memory 20 transmits a ready/busy signal RBn to the memory controller 10 via the memory bus. The ready/busy signal RBn is a signal indicating whether the NAND flash memory 20 is in a busy state in which it cannot receive a command CMD from the memory controller 10 or in a ready state in which it can receive a command CMD.

Next, an internal configuration of the NAND flash memory 20 will be described. The NAND flash memory 20 includes an input/output circuit 201, a logic control circuit 202, an address register 203, a command register 204, a status register 205, a sequencer 206, a ready/busy circuit 207, a voltage generator 208, and one or more planes PLN. Each plane PLN includes a memory cell array 209, a row decoder 210, a sense amplifier 211, a data register 212, and a column decoder 213.

The input/output circuit 201 inputs and outputs the signal DQ and the timing signals DQS and DQSn. The input/output circuit 201 is coupled to the memory controller 10 via the memory bus. The input/output circuit 201 is also coupled to the logic control circuit 202, the address register 203, the command register 204, the status register 205, and the data register 212 of each plane PLN.

If the input signal DQ is an address ADD, the input/output circuit 201 transmits the address ADD to the address register 203. If the input signal DQ is a command CMD, the input/output circuit 201 transmits the command CMD to the command register 204.

If the input signal DQ is data DAT, the input/output circuit 201 receives the input signal DQ based on the timing signals DQS and DQSn. Then, the input/output circuit 201 transmits the data DAT to the data register 212 of the plane PLN corresponding to an address ADD. The input/output circuit 201 also outputs data DAT to the memory controller 10 as the output signal DQ together with the timing signals DQS and DQSn.

The logic control circuit 202 is a circuit that performs a logic control based on the control signals. The logic control circuit 202 is coupled to the memory controller 10 via the memory bus. The logic control circuit 202 is also coupled to the input/output circuit 201 and the sequencer 206. The logic control circuit 202 receives the control signals from the memory controller 10. The logic control circuit 202 controls the input/output circuit 201 and the sequencer 206 based on the received control signals.

The address register 203 is a register that temporarily stores an address ADD. The address register 203 is coupled to the input/output circuit 201 and the row decoder 210 and the column decoder 213 of each plane PLN. The address ADD includes a row address RA and a column address CA. The address register 203 transfers the row address RA to the row decoder 210. The address register 203 also transfers the column address CA to the column decoder 213.

The command register 204 is a register that temporarily stores a command CMD. The command register 204 is coupled to the input/output circuit 201 and the sequencer 206. The command register 204 transfers the command CMD to the sequencer 206.

The status register 205 is a register that temporarily stores status information STS. For example, the status information STS includes information about results of a write operation, a read operation, an erase operation, and the like. The status register 205 is coupled to the input/output circuit 201 and the sequencer 206. For example, the input/output circuit 201 transmits the status information STS as the output signal DQ to the memory controller 10.

The sequencer 206 is a circuit that controls the entire NAND flash memory 20. The sequencer 206 is coupled to the logic control circuit 202, the command register 204, the status register 205, the ready/busy circuit 207, the voltage generator 208, and the row decoder 210 and the sense amplifier 211 of each plane PLN. For example, the sequencer 206 controls the status register 205, the ready/busy circuit 207, the voltage generator 208, and the row decoder 210 and the sense amplifier 211 of each plane PLN. The sequencer 206 executes a write operation, a read operation, an erase operation, and the like based on a command CMD.

The ready/busy circuit 207 is a circuit that generates the ready/busy signal RBn. The ready/busy circuit 207 is coupled to the memory controller 10 via the memory bus. The ready/busy circuit 207 is coupled to the sequencer 206. The ready/busy circuit 207 transmits the ready/busy signal RBn to the memory controller 10.

The voltage generator 208 generates various voltages used for the write operation, the read operation, and the erase operation under the control of the sequencer 206. The voltage generator 208 supplies various voltages to the memory cell array 209, the row decoder 210, the sense amplifier 211, and the like of each plane PLN.

The plane PLN is a unit in which the write operation, the read operation, and the erase operation are performed. In the example illustrated in FIG. 3, the NAND flash memory 20 includes two planes PLN0 and PLN1. The number of plane PLNs included in the NAND flash memory 20 is not limited to two. The planes PLN0 and PLN1 operate independently of each other. The planes PLN0 and PLN1 may operate in parallel. In other words, the NAND flash memory 20 includes one or more planes PLN that can be controlled independently of each other.

Next, an internal configuration of the plane PLN will be described. The following description is based on the assumption that the planes PLN0 and PLN1 have the same configuration. Note that, the configuration of each plane PLN may be different.

The memory cell array 209 is a set of a plurality of memory cells arranged in a matrix. The memory cell array 209 includes a plurality of blocks BLK. In the example illustrated in FIG. 3, the memory cell array 209 includes four blocks BLK0, BLK1, BLK2, and BLK3. Note that, the number of blocks BLK included in the memory cell array 209 is not limited to four. The block BLK is a set of a plurality of memory cells from which data is collectively erased, for example. That is, the block BLK is a data erase unit. Details of a configuration of the block BLK will be described later.

The row decoder 210 is a circuit that decodes a row address RA. The row decoder 210 is coupled to the address register 203, the sequencer 206, the voltage generator 208, and the memory cell array 209. The row decoder 210 selects a block BLK in the memory cell array 209 based on the decoding result of the row address RA. The row decoder 210 applies voltages to interconnects (word lines and select gate lines to be described later) in the row direction of the selected block BLK.

The sense amplifier 211 is a circuit that writes and reads data DAT. The sense amplifier 211 is coupled to the sequencer 206, the voltage generator 208, the memory cell array 209, and the data register 212. The sense amplifier 211 reads data DAT from the memory cell array 209 during a read operation. The sense amplifier 211 also supplies voltages corresponding to data DAT to the memory cell array 209 during a write operation. The sense amplifier 211 includes a plurality of latch circuits for temporarily storing data.

The data register 212 is a register that temporarily stores data DAT. The data register 212 is coupled to the input/output circuit 201, the sense amplifier 211, and the column decoder 213. The data register 212 includes a plurality of latch circuits. Each latch circuit temporarily stores data DAT (write data) received from the input/output circuit 201 or data DAT (read data) received from the sense amplifier 211.

The column decoder 213 is a circuit that decodes a column address CA. The column decoder 213 is coupled to the address register 203 and the data register 212. The column decoder 213 receives the column address CA from the address register 203. The column decoder 213 selects one or more of the latch circuits in the data register 212 based on the decoding result of the column address CA.

### 1.1.5 Circuit Configuration of Memory Cell Array

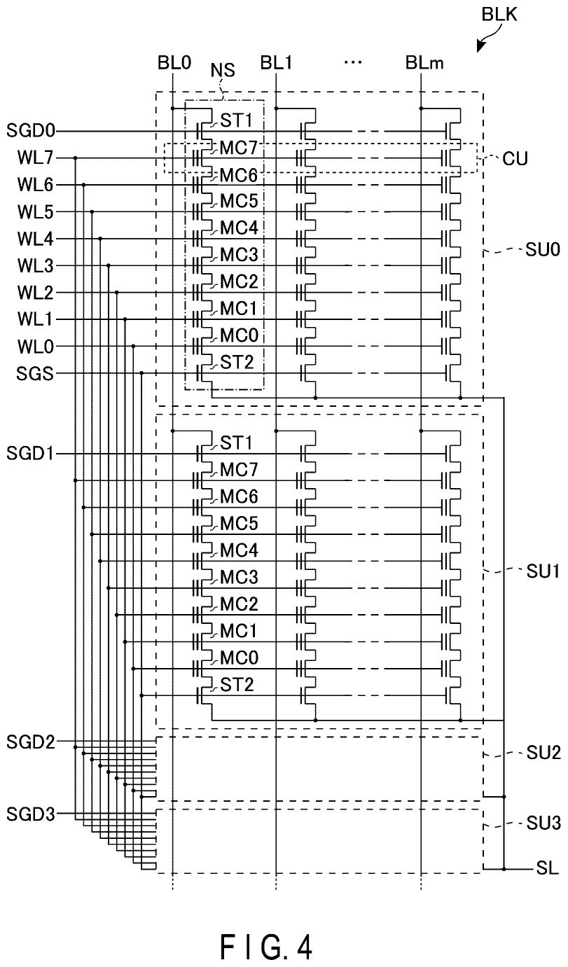

Next, an example of a circuit configuration of the memory cell array 209 will be described with reference to FIG. 4. FIG. 4 is a circuit diagram illustrating an example of a circuit configuration of the memory cell array 209. The example illustrated in FIG. 4 illustrates a circuit diagram of one block BLK.

As shown in FIG. 4, the block BLK includes a plurality of string units SU. In the example shown in FIG. 4, the block BLK includes four string units SU0 to SU3. Any number of string units SU may be included in the block BLK. The string unit SU is a set of a plurality of NAND strings NS.

The NAND string NS is a set of a plurality of memory cells MC coupled in series. Each of the plurality of NAND strings NS in the string unit SU is coupled to any one of bit lines BL0 to BLm (m is an integer of 1 or larger). Each NAND string NS includes the plurality of memory cells MC and select transistors ST1 and ST2. In the example illustrated in FIG. 4, the NAND string NS includes eight memory cells MC0 to MC7.

The memory cell MC is a memory element that stores data in a non-volatile manner. The memory cell MC includes a control gate and a charge storage layer. The memory cell MC may be a floating gate (FG) type or a metal-oxide-nitride-oxide-silicon (MONOS) type.

The select transistors ST1 and ST2 are switching elements. The select transistors ST1 and ST2 are each used to select the string unit SU during various operations.

The current paths of the select transistor ST2, the memory cells MC0 to MC7, and the select transistor ST1 in the NAND string NS are coupled in series. The drain of the select transistor ST1 is coupled to the bit line BL. The source of the select transistor ST2 is coupled to a source line SL.

The control gates of the plurality of memory cells MC0 to MC7 of the same block BLK are coupled in common to the word lines WL0 to WL7, respectively. More specifically, for example, each of the string units SU0 to SU3 includes a plurality of memory cells MC0. The control gates of the plurality of memory cells MC0 in the block BLK are coupled to one word line WL0. The same applies to the memory cells MC1 to MC7.

The gates of the plurality of select transistors ST1 in each string unit SU are coupled in common to one select gate line SGD. More specifically, the gates of the plurality of select transistors ST1 in the string unit SU0 are coupled in common to a select gate line SGD0. Similarly, the gates of the plurality of select transistors ST1 in the string unit SU1 are coupled in common to a select gate line SGD1. The gates of the plurality of select transistors ST1 in the string unit SU2 are coupled in common to a select gate line SGD2. The gates of the plurality of select transistors ST1 in the string unit SU3 are coupled in common to a select gate line SGD3.

The gates of the plurality of select transistors ST2 in the block BLK are coupled in common to a selection gate line SGS.

The word lines WL0 to WL7, the select gate lines SGD0 to SGD3, and the select gate line SGS are coupled to the row decoder 210.

The bit lines BL are coupled in common to one NAND string NS of each of the plurality of string units SU of each block BLK. Each bit line BL is coupled to the sense amplifier 211.

The source line SL is shared among the plurality of blocks BLK, for example.

A set of a plurality of memory cells MC coupled in common to one word line WL in one string unit SU will be referred to as a cell unit CU, for example. In other words, the cell unit CU is a set of a plurality of memory cells MC collectively selected in a write operation or a read operation. The page is a unit of data that is collectively written (or collectively read) to the cell unit CU. For example, if the memory cell MC stores 1-bit data, the storage capacity of the cell unit CU is one page. That is, the cell unit CU stores 1-page data. One page may have the same data length as the ECC frame, or one page may include a plurality of ECC frames. Hereinafter, a case where one page has the same data length as the data length of the ECC frame will be described. Note that, the cell unit CU may have a storage capacity of two or more pages based on the number of bits of data stored in the memory cell MC.

Hereinafter, a case where the memory cell MC is a triple level cell (TLC) that stores 3-bit data will be described. If the memory cell MC is the TLC, 3-page data is stored in the cell unit CU. Note that, the memory cell MC is not limited to the TLC. For example, the memory cell MC may be a single level cell (SLC) that stores 1-bit data, may be a multi level cell (MLC) that stores 2-bit data, may be a quad level cell (QLC) that stores 4-bit data, or may be a penta level cell (PLC) that stores 5-bit data.

### 1.1.6 Threshold Voltage Distribution of Memory Cell

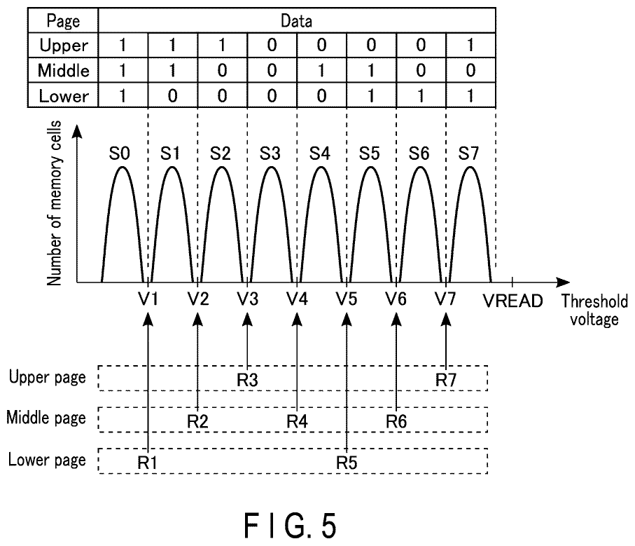

Next, an example of the threshold voltage distributions of the memory cells MC will be described with reference to FIG. 5. FIG. 5 is a diagram illustrating threshold voltage distributions and data assignment in a case where the memory cell MCs are TLCs.

As illustrated in FIG. 5, if the memory cell MC stores 3-bit data, the distributions of the threshold voltages are divided into eight. These eight threshold voltage distributions (threshold voltage ranges) will be referred to as an S0 state to an S7 state in the ascending order of the threshold voltage.

Voltages V1 to V7 are verify voltages that are used in verify operations of the S0 state to the S7 state during a write operation. A voltage VREAD is a voltage applied to non-selected word lines WL during a read operation. When the voltage VREAD is applied to the gate of a memory cell MC, the memory cell MC is turned on regardless of data stored therein. The relationship among the voltages V1 to V7 and the voltage VREAD is V1<V2<V3<V4<V5<V6<V7<VREAD.

The S0 state corresponds to an erased state of the memory cell MC. The S1 state to S7 state correspond to states in which charges are injected into the charge storage layer of the memory cell MC and data is written. The threshold voltage of the memory cell MC included in the S0 state is lower than the voltage V1. The threshold voltages of the memory cells MC included in the S1 to S6 states are respectively equal to or higher than the voltage V1 and lower than the voltage V2, to, equal to or higher than the voltage V6 and lower than the voltage V7. The threshold voltage of the memory cell MC included in the S7 state is equal to or higher than the voltage V7 and lower than the voltage VREAD.

The set value of the verify voltage and the set value of the read voltage corresponding to each state may be the same or different. Hereinafter, in order to simplify the description, a case where the verify voltage and the read voltage have the same set value will be described.

Hereinafter, read operations using the voltages V1 to V7 will be referred to as read operations R1 to R7, respectively. In the read operation R1, it is determined whether the threshold voltage of a memory cell MC is lower than the voltage V1. In the read operation R2, it is determined whether the threshold voltage of a memory cell MC is lower than the voltage V2. In the read operation R3, it is determined whether the threshold voltage of a memory cell MC is lower than the voltage V3. The same applies to the other read operations.

As described above, the threshold voltage of each memory cell MC belongs to one of the eight threshold voltage distributions. Accordingly, each memory cell MC can be in eight types of states. Assigning these states to data “000” to “111” expressed in binary numbers allows each memory cell MC to store 3-bit data. Hereinafter, the 3-bit data will be referred to as a lower bit, a middle bit, and an upper bit in order from the least significant bit. In addition, a set of lower bits, a set of middle bits, and a set of upper bits stored in the memory cells MC included in the same cell unit CU will be respectively referred to as lower page data, middle page data, and upper page data.

In the example illustrated in FIG. 5, data of upper bit/middle bit/lower bit is assigned to the memory cells MC included in each state as follows.
S0 state: “111” data
S1 state: “110” data
S2 state: “100” data
S3 state: “000” data
S4 state: “010” data
S5 state: “011” data
S6 state: “001” data
S7 state: “101” data

In reading the data assigned in this manner, the lower bit is determined by the read operations R1 and R5. The middle bit is determined by the read operations R2, R4, and R6. The upper bit is determined by the read operations R3 and R7. The values of the lower bit, the middle bit, and the upper bit are determined by two, three, and two read operations, respectively. Hereinafter, this data assignment will be referred to as 2-3-2 code. The data assignment to the S0 to S7 states is not limited to the 2-3-2 code.

### 1.2 Read Operation

Next, the read operation will be described. The read operation includes a hard bit read operation (hereinafter, also referred to as an HB read) and a soft bit read operation (hereinafter, also referred to as an SB read).

The HB read is an operation of reading HB data. In the HB read, one read voltage (hereinafter, also referred to as an HB read voltage) is set for each boundary of the threshold voltage distributions of the memory cells MC. In other words, one HB read voltage is set for each state. The sequencer 206 executes a read operation using the HB read voltage. The hard bit has a value obtained by determining whether the threshold voltage of a memory cell MC is lower than the HB read voltage (that is, whether the memory cell MC turns on) in the read operation using the HB read voltage. For example, each of the read operations R1 to R7 described with reference to FIG. 5 corresponds to the HB read. In this case, each of the read voltages V1 to V7 corresponds to the HB read voltage. The hard bit is a result of a read operation to determine the value of each bit (lower bit, middle bit, and upper bit) of a memory cell MC.

The SB read is an operation of reading SB data. In the SB read, a plurality of voltages (hereinafter, also referred to as SB read voltages) with reference to the HB read voltage are set for each boundary of the threshold voltage distributions of the memory cells MC. In other words, a plurality of SB read voltages are set for each state. The sequencer 206 executes a plurality of read operations using the plurality of SB read voltages. The soft bit has a value obtained by determining whether the threshold voltage of a memory cell MC is lower than the SB read voltage (that is, whether the memory cell MC turns on) in the read operation using the SB read voltage. The soft bit is used to calculate the likelihood of the hard bit of the corresponding memory cell MC. The CPU 12 calculates the likelihood of the hard bit based on the hard bit and the soft bit. One or more soft bits are acquired for data stored in one memory cell MC. That is, one or more pieces of SB data are acquired by the SB read. Note that, the sequencer 206 may execute a logical operation using a plurality of read results obtained by using the plurality of SB read voltages, and may use the operation result as a soft bit.

### 1.2.1 Specific Examples of HB Data and SB Data

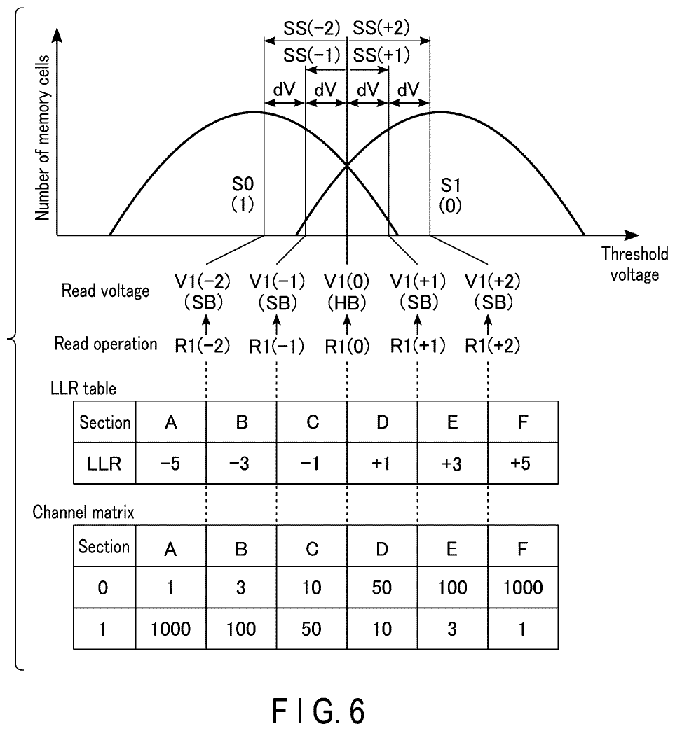

Next, specific examples of the HB data and the SB data will be described with reference to FIG. 6. FIG. 6 is a diagram illustrating an example of a relationship among threshold voltage distributions of the S0 state and the S1 state, the HB read voltage and the SB read voltages, the LLR table, and the channel matrix. Hereinafter, description will be given focusing on the S0 state and the S1 state in the read operation of the lower bit. For example, “1” data is assigned to the S0 state, and “0” data is assigned to the S1 state.

As illustrated in FIG. 6, due to the influence of read disturb, data retention, or the like, the width of the threshold voltage distribution of each state is widened, and part of the threshold voltage distributions of adjacent states may overlap each other.

For example, the CPU 12 first causes the sequencer 206 to execute an HB read using the voltage V1(0) as the HB read voltage. Hereinafter, the read operation using the HB read voltage V1(0) will be referred to as a read operation R1(0). Here, the HB read voltage V1(0) may be the same voltage value as the voltage V1 (default read voltage) described with reference to FIG. 5, or may be a voltage obtained by shifting the voltage V1 based on a shift value (hereinafter, referred to as an HB shift value). For example, when the HB shift value of the HB read voltage V1(0) is denoted as HS, the HB read voltage V1(0) and the default read voltage V1 have a relationship of V1(0)=V1+HS. In order to simplify the description, it is assumed hereinafter that the default read voltage V1 and the HB read voltage V1(0) are the same voltage value, that is, the HB shift value HS is zero.

As a result of the execution of the HB read by the sequencer 206, a memory cell MC corresponding to the overlapping region of the threshold voltage distributions is likely to be a fail bit. More specifically, for example, a memory cell MC having the threshold voltage of the S0 state at the completion of the write operation and having the threshold voltage equal to or higher than the HB read voltage V1(0) at the execution of the HB read is a fail bit. In addition, a memory cell MC having the threshold voltage of the S1 state at the completion of the write operation and having the threshold voltage lower than the HB read voltage V1(0) at the execution of the HB read is a fail bit. If the number of fail bits exceeds the number of error-correctable bits, the hard bit decoding circuit 162 fails in the HB decoding. In that case, the CPU 12 causes the sequencer 206 to execute the SB read.

The sequencer 206 performs the SB read using a plurality of SB read voltages. In the example illustrated in FIG. 6, four voltages V1(−2), V1(−1), V1(+1), and V1(+2) are set as the SB read voltages. The SB read voltages V1(−2) and V1(−1) are voltages obtained by shifting the HB read voltage V1(0) to the low voltage side. The SB read voltages V1(+1) and V1(+2) are voltages obtained by shifting the HB read voltage V1(0) to the high voltage side. The HB read voltage V1(0) and the SB read voltages V1 (−2), V1 (−1), V1 (+1), and V1 (+2) have a relationship of V1(−2)<V1(−1)<V1 (0)<V1(+1)<V1(+2). Hereinafter, the shift values used for setting the SB read voltages V1 (−2), V1 (−1), V1 (+1), and V1 (+2) will be referred to as SB shift values SS(−2), SS(−1), SS(+1), and SS(+2), respectively. The SB read voltages V1(−2), V1(−1), V1(+1), and V1(+2) can be expressed by the following formulas using the HB read voltage V1(0) and the SB shift values SS(−2), SS(−1), SS(+1), and SS (+2):

$$V 1 ( - 2 ) = V 1 ( 0 ) + SS ( - 2 ) \\ V 1 ( - 1 ) = V 1 ( 0 ) + SS ( - 1 ) \\ V 1 ( + 1 ) = V 1 ( 0 ) + SS ( + 1 ) \\ V 1 ( + 2 ) = V 1 ( 0 ) + SS ( + 2 )$$

For example, if the interval between the read voltages is a constant value dV, the read information generation circuit 17 sets −2dV, −dV, dV, and 2dV as the SB shift values SS (−2), SS (−1), SS (+1), and SS (+2), respectively. The SB read voltages V1(−2), V1(−1), V1(+1), and V1(+2) can be expressed by the following formulas using the HB read voltage V1(0) and the SB shift values −2dV, −dV, dV, and 2 dV:

$$V 1 ( - 2 ) = V 1 ( 0 ) + SS ( - 2 ) = V 1 ( 0 ) - 2 dV \\ V 1 ( - 1 ) = V 1 ( 0 ) + SS ( - 1 ) = V 1 ( 0 ) - dV \\ V 1 ( + 1 ) = V 1 ( 0 ) + SS ( + 1 ) = V 1 ( 0 ) + dV \\ V 1 ( + 2 ) = V 1 ( 0 ) + SS ( + 2 ) = V 1 ( 0 ) + 2 dV$$

The number of the SB read voltages is not limited to two for each of the low voltage side and the high voltage side with respect to the HB read voltage. In addition, the interval between the read voltages may be different for each SB read voltage. For example, the interval between the HB read voltage V1(0) and the SB read voltage V1(−1) and the interval between the SB read voltage V1(−1) and the SB read voltage V1(−2) may be different from each other.

In the SB read, the sequencer 206 executes the read operations R1(−2), R1(−1), R1(+1), and R1(+2) corresponding to the SB read voltages V1(−2), V1(−1), V1(+1), and V1(+2), respectively. For example, the sequencer 206 transmits data of the read operations R1(−2), R1(−1), R1(+1), and R1(+2) as SB data to the memory controller 10. Note that, the sequencer 206 may calculate the SB data by executing arithmetic processing using the data of the read operations R1(−2), R1(−1), R1(+1), and R1(+2). For example, the sequencer 206 may calculate first SB data by a negative exclusive OR (ENOR) operation using data of the read operation R1(−2) and data of the read operation R1(+2), and calculate second SB data by an ENOR operation using data of the read operation R1(−1) and data of the read operation R1 (+1).

In the example illustrated in FIG. 6, the threshold voltage range of a memory cell MC is classified into six sections A to F corresponding to the HB read voltage V1 (0) and the four SB read voltages V1 (−2), V1 (−1), V1 (+1), and V1 (+2). Specifically, the threshold voltage range of the section A is lower than the SB read voltage V1(−2). The threshold voltage range of the section B is equal to or higher than the SB read voltage V1(−2) and lower than the SB read voltage V1(−1). The threshold voltage range of the section C is equal to or higher than the SB read voltage V1(−1) and lower than the HB read voltage V1(0). The threshold voltage range of the section D is equal to or higher than the HB read voltage V1(0) and lower than the SB read voltage V1(+1). The threshold voltage range of the section E is equal to or higher than the SB read voltage V1(+1) and lower than the SB read voltage V1(+2). The threshold voltage range of the section F is equal to or higher than the SB read voltage V1(+2).

In the LLR table 141, preset LLRs are stored for each section. In the example illustrated in FIG. 6, LLRs for the sections A, B, C, D, E, and F are −5, −3, −1, +1, +3, and +5. The sign (+, −) of the LLR is inverted between the section C and the section D. Since the LLRs of the sections A, B, and C are negative values, there is a high probability that data written to memory cells MC having the threshold voltages in these sections is “1”. Since the LLRs of the sections D, E, and F are positive values, there is a high probability that data written to memory cells MC having the threshold voltages in these sections is “0”. Note that, a plurality of the LLR tables 141 may be provided in consideration of the fluctuation of the threshold voltage of a memory cell MC.

The channel matrix is a result of counting, for each section, the number of memory cells MC in which “0” is written and the number of memory cells MC in which “1” is written at the time of a write operation, among the memory cells MC having the threshold voltages in the range of the section. For example, if the SB decoding has succeeded, the DLE calculation circuit 164 generates a channel matrix based on the success data (decoded write data). On the other hand, if the SB decoding has failed, the DLE calculation circuit 164 generates a channel matrix based on the failure data, on the assumption that the failure data is approximately the same as the write data.

In the example illustrated in FIG. 6, in the section A, the number of counts of “0” is 1 and the number of counts of “1” is 1000. In the section B, the number of counts of “0” is 3 and the number of counts of “1” is 100. In the section C, the number of counts of “0” is 10 and the number of counts of “1” is 50. Therefore, in the sections A, B, and C, the counted number of “1” is larger than the counted number of “0”. In the section D, the number of counts of “0” is 50 and the number of counts of “1” is 10. In the section E, the number of counts of “0” is 100 and the number of counts of “1” is 3. In the section F, the number of counts of “0” is 1000 and the number of counts of “1” is 1. Therefore, in the sections D, E, and F, the counted number of “0” is larger than the counted number of “1”.

A transmission value from the memory controller 10 to the NAND flash memory 20, that is, a data string corresponding to the write data is represented by x={x₁, x₂, . . . xₙ}(n is a natural number). Further, a transmission value from the NAND flash memory 20 to the memory controller 10, that is, a data string corresponding to the read data is represented by y={y₁, y₂, . . . yₙ}. In this case, the LLR of a memory cell MC corresponding to the i-th data (i is a natural number that is equal to or larger than 1 and equal to or smaller than n) in the data string is calculated by formula (1).

$$LLRi = log \frac{P ( {y}_{i} \vert {x}_{i} = 0 )}{P ( {y}_{i} \vert {x}_{i} = 1 )} \qquad ( 1 )$$

In formula (1), P(y₁|x₁=0) indicates a probability that read data is y₁ from a memory cell MC whose write data x₁ is “0”. Similarly, P (y₁|x₁=1) indicates a probability that read data is y₁ from a memory cell MC whose write data x₁ is “1”. In the present embodiment, as the write data x₁, data of the memory cell MC corresponding to the i-th data in the failure data is used. Further, as the read data y₁, data before error correction read from the memory cell MC corresponding to the i-th data is used.

Therefore, the LLR corresponding to a certain section y is calculated by formula (2).

$$LLRy = log \frac{P ( y \vert x = 0 )}{P ( y \vert x = 1 )} \qquad ( 2 )$$

In formula (2), P(y|x=0) corresponds to a value obtained by dividing the counted number of “0” in the section y in the read data (i.e., data before error correction) by the total number of “0” counted in all the sections in the failure data in the channel matrix. Similarly, P(y|x=1) corresponds to a value obtained by dividing the counted number of “1” in the section y in the read data (i.e., data before error correction) by the total number of “1” counted in all the sections in the failure data. The LLRy obtained by using the read data (i.e., data before error correction) and the failure data in this manner is the DLE1 corresponding to the section y.

### 1.2.2 Shift Value Correction Process of Read Voltage

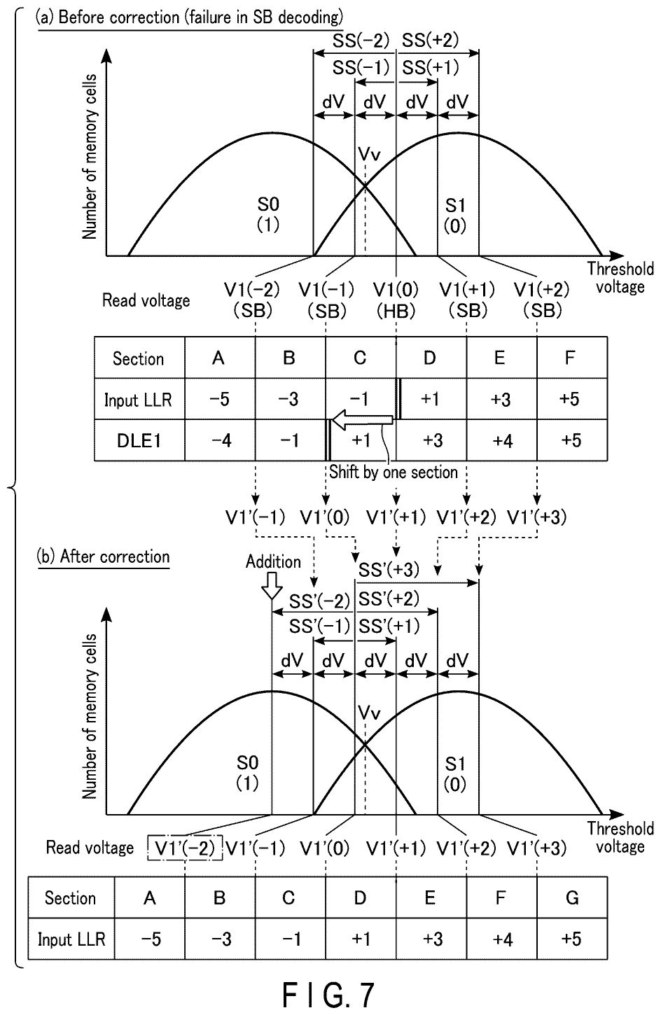

Next, an example of a shift value correction process of a read voltage will be described with reference to FIG. 7. FIG. 7 is a diagram illustrating an example of a shift value correction process of a read voltage. FIG. 7(a) illustrates the relationships among the threshold voltage distributions of the S0 state and the S1 state, the HB read voltage and the SB read voltages before correction (i.e., a state in which SB decoding has failed), the input LLR before correction, and DLE1. FIG. 7(b) illustrates the relationships among the threshold voltage distributions of the S0 state and the S1 state, the HB read voltage and the SB read voltages after correction, and the input LLR after correction.

As illustrated in FIG. 7(a), for example, the position (voltage Vv) where the threshold voltage distribution of the S0 state and the threshold voltage distribution of the S1 state intersect is shifted to the low voltage side with respect to the HB read voltage V1(0). The voltage difference between the voltage Vv and the SB read voltage V1(−1) is smaller than the voltage difference between the voltage Vv and the HB read voltage V1(0). If the voltage difference between the voltage Vv and the HB read voltage V1(0) increases, the number of fail bits increases. If the number of fail bits exceeds the number of error-correctable bits, the hard bit decoding circuit 162 fails in the HB decoding.

If the hard bit decoding circuit 162 has failed in the HB decoding, the soft bit decoding circuit 163 executes the SB decoding using the HB data, the SB data, and the input LLR. The input LLR indicates an LLR input to the soft bit decoding circuit 163. The input LLR before correction is based on the LLR table 141 described with reference to FIG. 6. In the example illustrated in FIG. 7(a), the input LLRs for the sections A, B, C, D, E, and F are −5, −3, −1, +1, +3, and +5, respectively, like in the example illustrated in FIG. 6.

If the soft bit decoding circuit 163 has failed in the SB decoding, the DLE calculation circuit 164 generates a channel matrix using the failure data of the failed SB decoding. Then, the DLE calculation circuit 164 calculates DLE1 based on the channel matrix. In the example illustrated in FIG. 7(a), the values of DLE1 in the sections A, B, C, D, E, and F are −4, −1, +1, +3, +4, and +5. Here, the sign of the DLE1 is inverted between the sections B and C adjacent to each other. That is, the value of DLE1 in the section B is −1, and the DLE1 in the section C is +1. In the example illustrated in FIG. 7(a), a position (first position) between two sections where the sign of the input LLR is inverted (a position indicated by a double line in the input LLR in FIG. 7(a)) and a position (second position) between two sections where the sign of the DLE1 is inverted (a position indicated by a double line in DLE1 in FIG. 7(a)) are different (shifted) from each other.

The read information generation circuit 17 corrects the shift value. In other words, the read information generation circuit 17 changes the read voltage. First, the read information generation circuit 17 corrects the HB shift value based on the difference between the first position, which is between two sections in which the sign of the input LLR is inverted, and the second position, which is between two sections in which the sign of the DLE1 is inverted. It is estimated that there is a position between the two sections where the sign of the DLE1 is inverted, where the magnitude relationship between the number of pieces of “0” data and the number of pieces of “1” data in the write data is inverted. Thus, the read information generation circuit 17 corrects the HB shift value so that the post-correction HB read voltage is set at the position between the two sections where the sign of the DLE1 is inverted.

In the example illustrated in FIG. 7(a), the sign of the DLE1 is inverted between the section B and the section C that are adjacent to each other. Therefore, the read information generation circuit 17 corrects the HB shift value such that the HB read voltage V1(0) is shifted by one section to the low voltage side. In other words, the read information generation circuit 17 generates an HB shift value HS' of a post-correction HB read voltage V1′(0) such that the HB read voltage V1′(0) is set to the same voltage as the pre-correction SB read voltage V1(−1). More specifically, the read information generation circuit 17 adds the SB shift value SS(−1) of the SB read voltage V1(−1), that is, −dV, to the pre-correction HB shift value HS. Therefore, the HB shift value HS' can be expressed as HS′=HS−dV using the HB shift value HS and the SB shift value −dV. For example, if the default read voltage V1 and the HB read voltage V1(0) are the same, that is, if the HB shift value HS is 0, HS′ is expressed as HS′=−dV. The HB read voltage V1′(0) can be expressed as V1′(0)=V1(0)−dV using the pre-correction HB read voltage V1(0) and the HB shift value −dV.

Next, the read information generation circuit 17 sets SB read voltages based on the post-correction HB read voltage. In the present embodiment, the read information generation circuit 17 adds an SB read voltage at which the read operation is not executed in the pre-correction SB read. The read information generation circuit 17 determines the number of SB read voltages to be added, based on the number of sections in which the HB read voltage was shifted. In the example illustrated in FIG. 7(a), the post-correction HB read voltage V1′(0) is shifted by one section from the pre-correction HB read voltage V1(0) to the low voltage side. The pre-correction HB read voltage V1(0) and the SB read voltages V1(−2), V1(−1), V1(+1), and V1(+2) can be expressed by the following formulas using the post-correction HB read voltage V1′(0).

$$V 1 ( - 2 ) = V 1 ( 0 ) - 2 dV = V {1}^{′} ( 0 ) - dV = V {1}^{′} ( - 1 ) \\ V 1 ( - 1 ) = V 1 ( 0 ) - dV = V {1}^{′} ( 0 ) \\ V 1 ( 0 ) = V {1}^{′} ( 0 ) + dV = V {1}^{′} ( + 1 ) \\ V 1 ( + 1 ) = V 1 ( 0 ) + dV = V {1}^{′} ( 0 ) + 2 dV = V {1}^{′} ( + 2 ) \\ V 1 ( + 2 ) = V 1 ( 0 ) + 2 dV = V {1}^{′} ( 0 ) + 3 dV = V {1}^{′} ( + 3 )$$

Here, V1′(−1), V1′(+1), V1′(+2), and V1′(+3) are SB read voltages corresponding to the HB read voltage V1′(0).

There are two SB read voltages on the lower voltage side than the pre-correction HB read voltage V1(0), whereas the number of SB read voltages on the lower voltage side than the post-correction HB read voltage V1′(0) is reduced to one. On the other hand, there are two SB read voltages on the higher voltage side than the pre-correction HB read voltage V1(0), whereas the number of SB read voltages on the higher voltage side than the post-correction HB read voltage V1′(0) is increased to three.

As illustrated in FIG. 7(b), the read information generation circuit 17 adds an SB read voltage V1′(−2) such that the number of the post-correction SB read voltages on the low voltage side is the same as the number of the pre-correction SB read voltages (for example, two). That is, the read information generation circuit 17 sets the SB read voltages V1′(−2), V1′(−1), V1′(+1), V1′(+2), and V1′(+3) with reference to the post-correction HB read voltage V1′(0). The SB shift values used to set the SB read voltages V1′(−2), V1′(−1), V1′(+1), V1′(+2), and V1′(+3) are defined as SS′(−2), SS′(−1), SS′(+1), SS′(+2), and SS′(+3), respectively. If the read voltage interval dV is constant, the read information generation circuit 17 sets −2dV, −dV, dV, 2dV, and 3dV as the SB shift values SS′(−2), SS′(−1), SS′(+1), SS′(+2), and SS′(+3), respectively. In other words, the read information generation circuit 17 adds the SB shift value 3dV.

In the example illustrated in FIG. 7(b), the threshold voltage range of the memory cell MC is classified into seven sections A to G corresponding to the HB read voltage V1′(0) and the five SB read voltages V1′(−2), V1′(−1), V1′(+1), V1′(+2), and V1′(+3). Specifically, the threshold voltage range of the section A is lower than the SB read voltage V1′(−2). The threshold voltage range of the section B is equal to or higher than the SB read voltage V1′(−2) and lower than the SB read voltage V1′(−1). The threshold voltage range of the section C is equal to or higher than the SB read voltage V1′(−1) and lower than the HB read voltage V1′(0). The threshold voltage range of the section D is equal to or higher than the HB read voltage V1′(0) and lower than the SB read voltage V1′(+1). The threshold voltage range of the section E is equal to or higher than the SB read voltage V1′(+1) and lower than the SB read voltage V1′(+2). The threshold voltage range of the section F is equal to or higher than the SB read voltage V1′(+2) and lower than the SB read voltage V1′(+3). The threshold voltage range of the section G is equal to or higher than the SB read voltage V1′(+3).

The read information generation circuit 17 corrects the input LLR according to the changed sections. For example, with reference to the HB read voltage V1′(0), the read information generation circuit 17 uses DLE1 as the input LLR if the number of sections on the low voltage side or the high voltage side is increased, and uses the pre-correction input LLR as it is if the number of sections on the low voltage side or the high voltage side is the same. In the example illustrated in FIG. 7(b), since the number of sections on the low voltage side (three) of the HB read voltage V1′(0) is the same as that before the correction, the read information generation circuit 17 sets −5, −3, and −1 that are the same as those before the correction as the input LLRs for the sections A, B, and C, respectively. On the other hand, since the number of sections on the high voltage side of the HB read voltage V1′(0) is increased to four, the read information generation circuit 17 sets +1, +3, +4, and +5 of DLE1 as the input LLRs for the sections D, E, F, and G, respectively.

### 1.2.3 Procedure of Read Operation

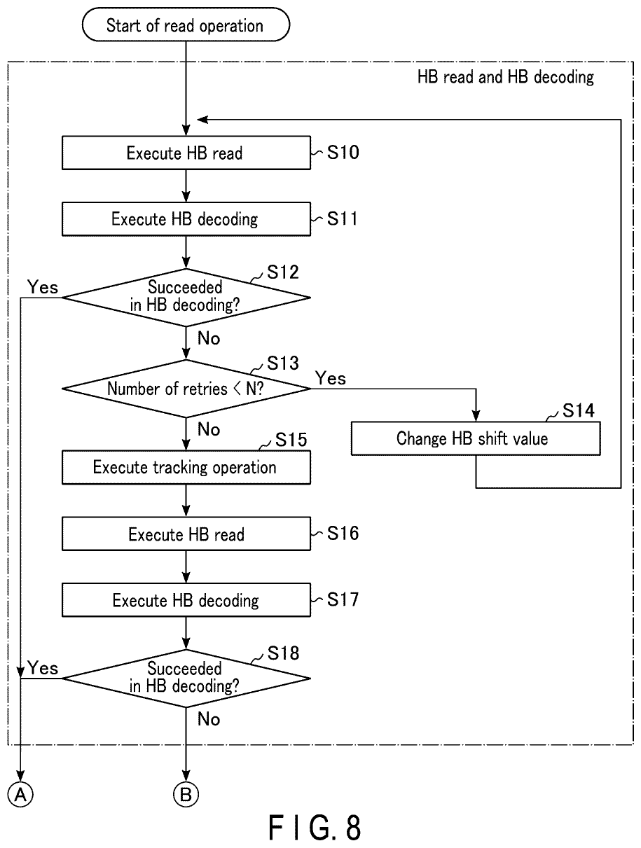

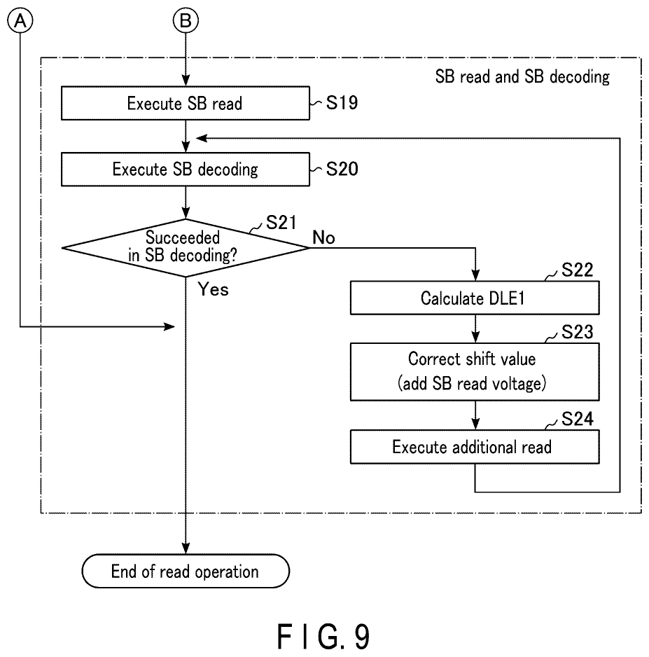

Next, an example of a procedure of a read operation will be described with reference to FIGS. 8 and 9. FIGS. 8 and 9 are flowcharts illustrating an example of an overall procedure of the read operation.

As illustrated in FIG. 8, upon receipt of a read request from the host 2, the memory controller 10 starts a read operation. The CPU 12 first executes the HB read and the HB decoding.

Specifically, the CPU 12 first causes the NAND flash memory 20 to execute the HB read (S10). The CPU 12 transmits a Set Feature related to the HB read voltage (HB shift value) and a command set of the HB read to the NAND flash memory 20, for example. The command set of the HB read includes an execution command of the HB read, an address of the target cell unit CU, and the like. The sequencer 206 sets the HB read voltage based on the HB shift value designated by the Set Feature. The sequencer 206 executes the HB read of data stored in the target cell unit CU. The sequencer 206 transmits the read data (HB data) to the memory controller 10. The HB data is stored in the buffer memory 15.

The hard bit decoding circuit 162 executes HB decoding using the HB data (S11).

If the hard bit decoding circuit 162 has succeeded in the HB decoding (S12_Yes), the CPU 12 transmits the error-corrected user data to the host 2 and ends the read operation.

If the hard bit decoding circuit 162 has failed in the HB decoding (S12_No), in step S13, the CPU 12 checks whether the number of retries of the HB decoding in the hard bit decoding circuit 162 is equal to or smaller than a preset number of times N (N is a natural number).

If the number of retries is smaller than N (S13_Yes), the read information generation circuit 17 changes the HB shift value (S14). For example, in the shift value information 142, a plurality of HB shift values may be provided in advance in consideration of variation of the threshold voltage of a memory cell MC. The read information generation circuit 17 refers to the shift value information 142 to change the HB shift value, for example. The CPU 12 causes the NAND flash memory 20 to execute the HB read based on the changed HB shift value (S10).

If the number of retries has reached N (S13_No), the CPU 12 causes the NAND flash memory 20 to execute a tracking operation (S15). The tracking operation is an operation for searching for (or calculating) an optimum HB read voltage. The tracking operation includes a plurality of read operations in which the HB read voltage is shifted. For example, the CPU 12 searches for a position where the threshold voltage distributions of adjacent states overlap each other from the variation in the number of memory cells MC (the number of on-cells) that turn on in each read operation in which the HB read voltage is shifted.

The CPU 12 causes the NAND flash memory 20 to execute the HB read (S16). More specifically, the CPU 12 transmits the command set of the Set Feature and the HB read related to an HB read voltage, as in step S10, based on the tracking operation to the NAND flash memory 20. The sequencer 206 executes the HB read using the HB read voltage designated by the Set Feature. The sequencer 206 transmits the read data (HB data) to the memory controller 10. The CPU 12 stores the HB data in the buffer memory 15.

The hard bit decoding circuit 162 executes HB decoding using the HB data (S17).

If the hard bit decoding circuit 162 has succeeded in the HB decoding (S18_Yes), the CPU 12 transmits the error-corrected user data to the host 2 and ends the read operation.

If the hard bit decoding circuit 162 has failed in the HB decoding (S18_No), the CPU 12 executes the SB read and the SB decoding as illustrated in FIG. 9. Specifically, the CPU 12 first causes the NAND flash memory 20 to execute the SB read (S19). The CPU 12 transmits a Set Feature related to the SB read voltages (SB shift values) and a command set of the SB read to the NAND flash memory 20, for example. The command set of the SB read includes an execution command of the SB read, an address of the target cell unit CU, and the like. The sequencer 206 sets the SB read voltages based on the SB shift values specified by the Set Feature. The sequencer 206 executes the SB read of the target cell unit CU. The sequencer 206 transmits the SB data to the memory controller 10. The SB data is stored in the buffer memory 15.

The soft bit decoding circuit 163 executes the SB decoding using the HB data, the SB data, and the input LLR (S20).

If the soft bit decoding circuit 163 has succeeded in the SB decoding (S21_Yes), the CPU 12 transmits the error-corrected user data to the host 2 and ends the read operation.

If the soft bit decoding circuit 163 has failed in the SB decoding (S21_No), the DLE calculation circuit 164 calculates DLE1 using the failure data (S22). If the soft bit decoding circuit 163 has failed in the SB decoding in step S21, there is a high possibility that the correction of the HB shift value by the tracking operation was insufficient.

The read information generation circuit 17 corrects the shift values based on the DLE1 (S23). More specifically, the read information generation circuit 17 first corrects the HB shift value. Next, the read information generation circuit 17 adds one or more SB read voltages so that the number of SB read voltages on the low voltage side and the high voltage side with respect to the post-correction HB read voltage is not decreased from that before the correction. That is, the read information generation circuit 17 adds one or more SB shift values. The read information generation circuit 17 corrects the input LLR based on the changed section.

The CPU 12 causes the NAND flash memory 20 to execute an additional read operation using the added SB read voltages (S24). For example, in the example illustrated in FIG. 7(b), the SB read voltage V1′(−2) is added. The results of the read operations using the SB read voltage V1′(−1), the HB read voltage V1′(0), and the SB read voltages V1′(+1), V1′(+2), and V1′(+3) have been acquired by the read operations using the SB read voltages V1(−2) and V1(−1), the HB read voltage V1(0), and the SB read voltages V1(+1) and V1(+2), respectively. Therefore, the CPU 12 causes the NAND flash memory 20 to execute an additional read operation using the SB read voltage V1′(−2). The sequencer 206 executes the additional read operation using the SB read voltage V1′(−2). The sequencer 206 transmits the SB data based on the SB read voltage V1′(−2) to the memory controller 10. The SB data based on the SB read voltage V1′(−2) is stored in the buffer memory 15. The soft bit decoding circuit 163 executes the SB decoding using the HB data corresponding to the HB read voltage V1′(0), the SB data corresponding to each of the SB read voltages V1′(−2), V1′(−1), V1′(+1), V1′(+2), and V1′(+3), and the corrected input LLR (S20). That is, the soft bit decoding circuit 163 retries the SB decoding.

### 1.3 Effects of Present Embodiment

According to the configuration in the present embodiment, if SB decoding has failed, the memory system 3 calculates DLE1 using failure data. Then, the memory system 3 corrects shift values of read voltages based on the DLE1. Using the result of the SB decoding allows the memory system 3 to improve the accuracy of the shift values. For example, even if decoding based on the shift values corrected by the tracking operation has failed, the memory system 3 can correct the shift values based on the DLE1. This improves the success rate of the SB decoding. Therefore, it is possible to improve data reliability.

Furthermore, according to the configuration in the present embodiment, the memory system 3 adds one or more SB read voltages based on the corrected shift values. The memory system 3 executes an additional read operation using only the added SB read voltages. Accordingly, in the case of retrying the SB decoding, an increase in the number of executions of the additional read operation can be suppressed. Therefore, it is possible to suppress an increase in the latency of the read operation of the memory system 3.

### 1.4 Modification of First Embodiment

Next, modifications of the first embodiment will be described. Hereinafter, two modifications of the shift value correction process of a read voltage different from that of the first embodiment will be described. Hereinafter, differences from the first embodiment will be mainly described.

### 1.4.1 First Modification of First Embodiment

First, a first modification of the first embodiment will be described. In the first modification of the first embodiment, a SB read voltage is replaced.

### 1.4.1.1 Shift Value Correction Process of Read Voltage

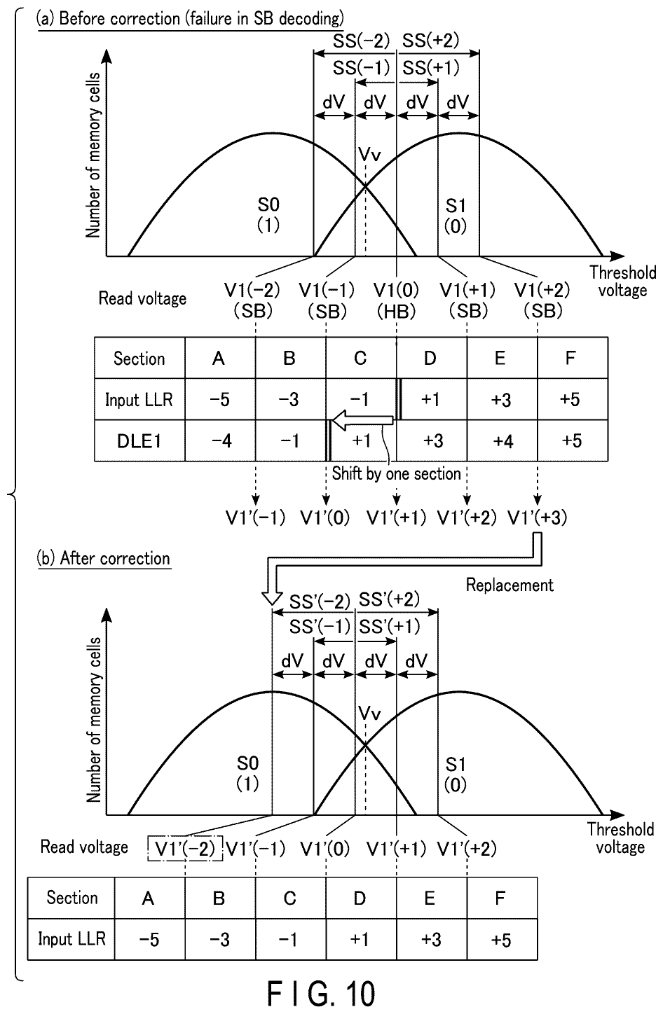

An example of the shift value correction process of a read voltage will be described with reference to FIG. 10. FIG. 10 is a Diagram Illustrating an example of the shift value correction process of a read voltage. FIG. 10(a) illustrates the relationships among the threshold voltage distributions of the S0 state and the S1 state, the HB read voltage and the SB read voltages before correction (i.e., a state in which SB decoding has failed), the input LLR before correction, and DLE1. FIG. 10(b) illustrates the relationships among the threshold voltage distributions of the S0 state and the S1 state, the HB read voltage and the SB read voltages after correction, and the input LLR after correction.

As illustrated in FIG. 10(a), a correction example of the HB shift value is similar to that in the first embodiment described using FIG. 7(a).

As illustrated in FIG. 10(b), the read information generation circuit 17 corrects an SB read voltage. In the present modification, the read information generation circuit 17 sets the SB read voltage such that the number of SB read voltages on the low voltage side and the number of SB read voltages on the high voltage side with respect to the HB read voltage V1′(0) are the same between before and after the correction. In the example illustrated in FIG. 10(a), the HB read voltage is shifted to the low voltage side by one section. Accordingly, the number of SB read voltages on the lower voltage side than the HB read voltage V1′(0) is decreased from two to one. In addition, the number of SB read voltages on the higher voltage side than the HB read voltage V1′(0) is increased from two to three. Therefore, the read information generation circuit 17 adds one SB read voltage to the low voltage side, thereby setting the number of SB read voltages on the low voltage side to two that is the same as that before the correction. The read information generation circuit 17 then deletes one SB read voltage on the high voltage side, thereby setting the number of SB read voltages on the high voltage side to two that is the same as that before the correction. More specifically, the read information generation circuit 17 adds an SB read voltage V1′(−2) to the low voltage side. Then, the read information generation circuit 17 deletes an SB read voltage V1′(+3) on the high voltage side. In other words, the read information generation circuit 17 replaces the SB read voltage V1′(+3) with the SB read voltage V1′(−2). As a result of replacing the SB read voltage, the number of SB read voltages on the low voltage side and the number of SB read voltages on the high voltage side with respect to the HB read voltage V1′(0) are the same as those before the correction. In this case, the read information generation circuit 17 sets the SB read voltages V1′(−2), V1′(−1), V1′(+1), and V1′(+2) with reference to the post-correction HB read voltage V1′(0). If an interval dV between the read voltages is constant, the read information generation circuit 17 sets −2dV, −dV, dV, and 2dV as SB shift values SS′(−2), SS′(−1), SS′(+1), and SS′(+2), respectively. Therefore, in the present modification, the read information generation circuit 17 does not change the SB shift value in the correction process of the shift value. In this case, the read information generation circuit 17 can use the same LLR as that before the correction as the post-correction input LLR.

### 1.4.1.2 Procedure of Read Operation

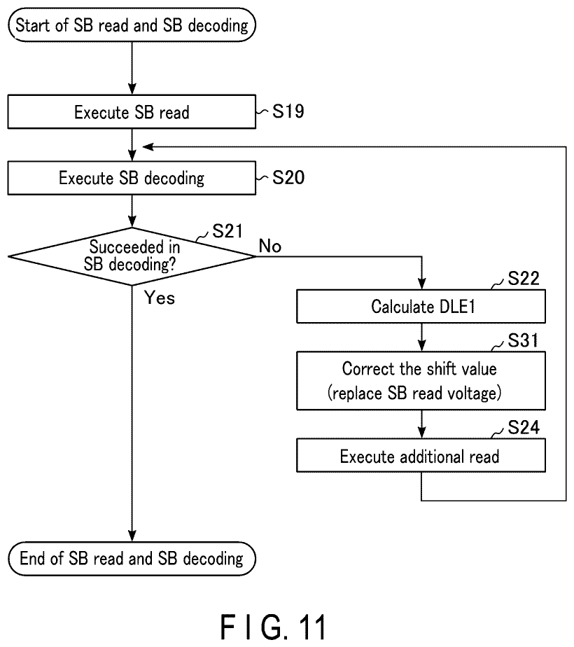

Next, an example of a procedure of a read operation will be described with reference to FIG. 11. FIG. 11 is a flowchart illustrating an example of steps of an SB read and SB decoding. FIG. 11 illustrates steps of the SB read and the SB decoding in the entire procedure of the read operation. In the entire procedure of the read operation, the steps of an HB read and HB decoding are similar to steps S10 to S18 in the first embodiment described with reference to FIG. 8.

As described in the first embodiment with reference to FIG. 8, if the HB decoding has failed (S18_No), the CPU 12 executes the SB read and the SB decoding.

As illustrated in FIG. 11, steps S19 to S22 are similar to those in the first embodiment described with reference to FIG. 9. If the soft bit decoding circuit 163 has succeeded in the SB decoding (S21_Yes), the CPU 12 ends the SB read and the SB decoding. That is, the CPU 12 transmits the error-corrected user data to the host 2 and ends the read operation.

If the soft bit decoding circuit 163 has failed in the SB decoding (S21_No), the DLE calculation circuit 164 calculates DLE1 using the failure data (S22). After the calculation of DLE1, the read information generation circuit 17 corrects the shift value based on the DLE1 (S31). More specifically, the read information generation circuit 17 first corrects the HB shift value. Next, the read information generation circuit 17 replaces an SB read voltage so that the number of SB read voltages on the low voltage side and the number of the SB read voltages on the high voltage side with respect to the post-correction HB read voltage are the same as those before the correction.

The CPU 12 executes an additional read operation using the replaced SB read voltage (S24). More specifically, in the example illustrated in FIG. 10(b), for example, the SB read voltage V1′(+3) is replaced with the SB read voltage V1′(−2). The results of the read operations using the SB read voltage V1′(−1), the HB read voltage V1′(0), and the SB read voltages V1′(+1) and V1′(+2) have been acquired by the read operations using the SB read voltages V1(−2) and V1(−1), the HB read voltage V1 (0), and the SB read voltage V1(+1), respectively. Therefore, the CPU 12 causes the NAND flash memory 20 to execute an additional read operation using the SB read voltage V1′(−2). The sequencer 206 executes the additional read operation using the SB read voltage V1′(−2). The sequencer 206 transmits the SB data based on the SB read voltage V1′(−2) to the memory controller 10. The SB data based on the SB read voltage V1′(−2) is stored in the buffer memory 15. The CPU 12 deletes the SB data based on the replaced SB read voltage V1′(+3), which corresponds to the pre-correction SB read voltage V1(+2), from the buffer memory 15. The soft bit decoding circuit 163 executes the SB decoding using the HB data corresponding to the HB read voltage V1′(0), the SB data corresponding to each of the SB read voltages V1′(−2), V1′(−1), V1′(+1), and V1′(+2), and the input LLR (S20). That is, the soft bit decoding circuit 163 retries the SB decoding.

### 1.4.1.3 Effects of Present Modification

According to the configuration of the present modification, the memory system 3 can improve the reliability of data as in the first embodiment.

Furthermore, according to the configuration in the present modification, the memory system 3 replaces a SB read voltage based on the corrected shift value. Accordingly, in the case of retrying the SB decoding, the soft bit decoding circuit 163 can use the same input LLR as before the correction.

### 1.4.2 Second Modification of First Embodiment

Next, a second modification of the first embodiment will be described. In the second modification of the first embodiment, after replacement of an SB read voltage, a plurality of read operations is executed using all of HB read voltages and SB read voltages.

### 1.4.2.1 Shift Value Correction Process of Read Voltage

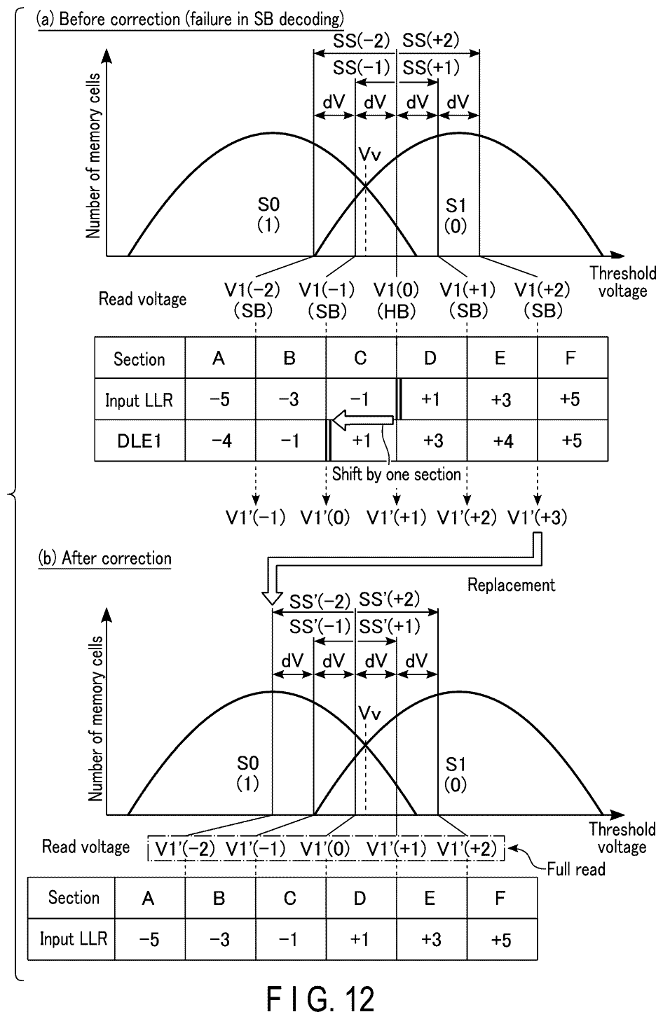

An example of the shift value correction process of a read voltage will be described with reference to FIG. 12. FIG. 12 is a diagram illustrating an example of the shift value correction process of a read voltage. FIG. 12(a) illustrates the relationships among the threshold voltage distributions of the S0 state and the S1 state, the HB read voltage and the SB read voltages before correction (i.e., a state in which SB decoding has failed), the input LLR before correction, and DLE1. FIG. 12(b) illustrates the relationships among the threshold voltage distributions of the S0 state and the S1 state, the HB read voltage and the SB read voltage after correction, and the input LLR after correction.

As illustrated in FIG. 12(a), a correction example of the HB shift value is similar to that in the first embodiment described using FIG. 7(a).

As illustrated in FIG. 12(b), the read information generation circuit 17 corrects an SB read voltage. The correction example of the SB read voltage is similar to that of the first modification of the first embodiment described with reference to FIG. 10(b). The read information generation circuit 17 replaces the SB read voltage V1′(+3) with the SB read voltage V1′(−2). In this case, the read information generation circuit 17 does not change the SB shift value. Therefore, the read information generation circuit 17 can use the same LLR as that before the correction as the input LLR. In the present modification, the CPU 12 executes a plurality of read operations (hereinafter, referred to as a full read operation) using the corrected HB read voltage V1′(0) and the SB read voltages V1′(−2), V1′(−1), V1′(+1), and V1′(+2), respectively.

### 1.4.2.2 Procedure of Read Operation

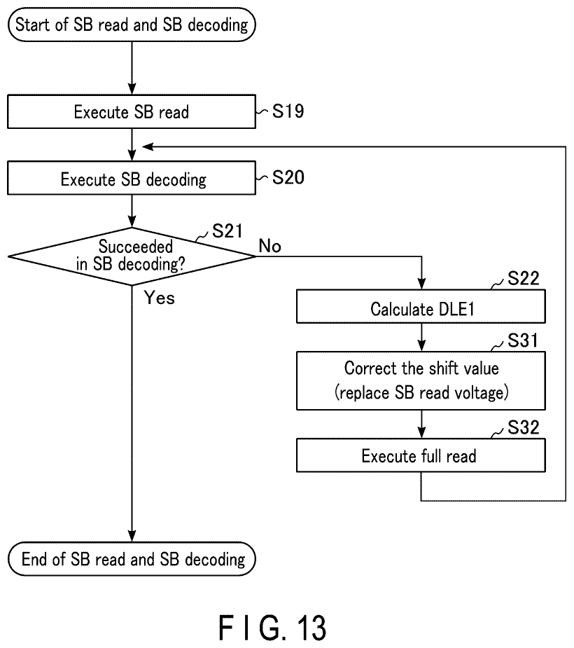

Next, an example of a procedure of a read operation will be described with reference to FIG. 13. FIG. 13 is a flowchart illustrating an example of steps of an SB read and SB decoding. FIG. 13 illustrates steps of the SB read and the SB decoding in the entire procedure of the read operation. In the entire procedure of the read operation, the steps of an HB read and HB decoding are similar to steps S10 to S18 in the first embodiment described with reference to FIG. 8.

As described in the first embodiment with reference to FIG. 8, if the HB decoding has failed (S18_No), the CPU 12 executes the SB read and the SB decoding.

As illustrated in FIG. 13, steps S19 to S22 and S31 are similar to those of the first modification of the first embodiment described with reference to FIG. 11. After replacing the SB read voltage in step S31, the CPU 12 executes the full read operation using the post-correction HB read voltage and SB read voltages (S32). The sequencer 206 transmits the HB data and the SB data based on the full read operation to the memory controller 10. The HB data and the SB data are stored in the buffer memory 15. The soft bit decoding circuit 163 executes the SB decoding using the HB data corresponding to the HB read voltage V1′(0), the SB data corresponding to each of the SB read voltages V1′(−2), V1′(−1), V1′(+1), and V1′(+2), and the input LLR (S20). That is, the soft bit decoding circuit 163 retries the SB decoding.

### 1.4.2.3 Effects of Present Modifications

According to the configuration of the present modifications, the memory system 3 can improve the reliability of data as in the first embodiment.

Furthermore, according to the configuration in the first modification, the memory system 3 replaces an SB read voltage based on the corrected shift value. Accordingly, in the case of retrying the SB decoding, the soft bit decoding circuit 163 can use the same LLR as before the correction.

Furthermore, according to the configuration in the second modification, the memory system 3 executes the full read operation based on the corrected HB read voltage and SB read voltages. For example, in a case where the soft bit is a result of a logical operation on a plurality of pieces of read data using a plurality of SB read voltages, the memory system 3 can calculate the SB data using the result of executing the full read operation.

### 2. Second Embodiment

Next, a second embodiment will be described. In the second embodiment, the interval between read voltages (a threshold voltage range defining each section) is adjusted in the event of a failure of the SB decoding. Hereinafter, differences from the first embodiment will be mainly described.

### 2.1 Shift Value Correction Process of Read Voltage

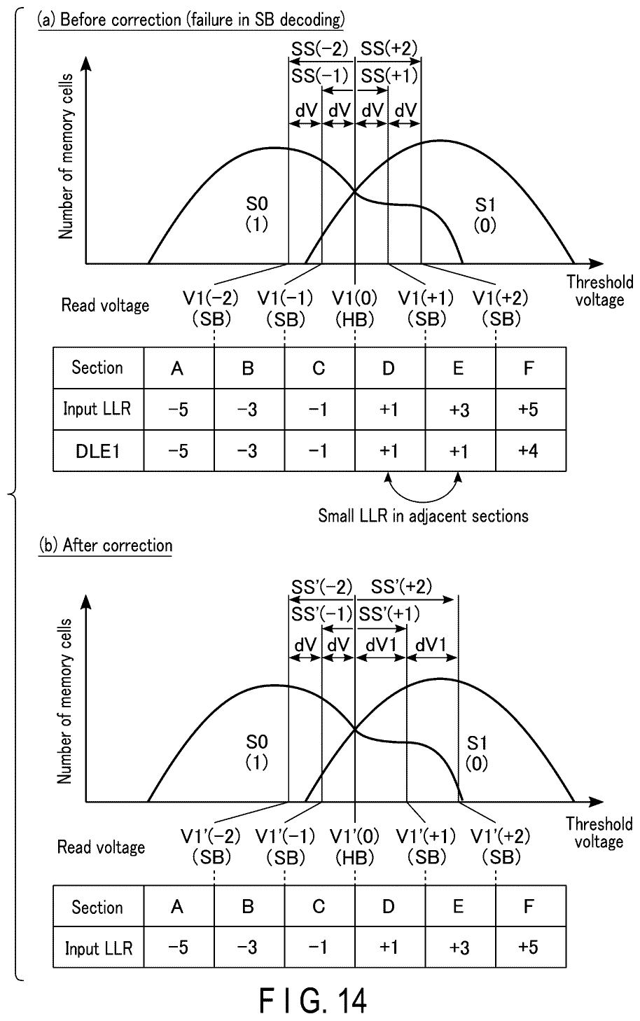

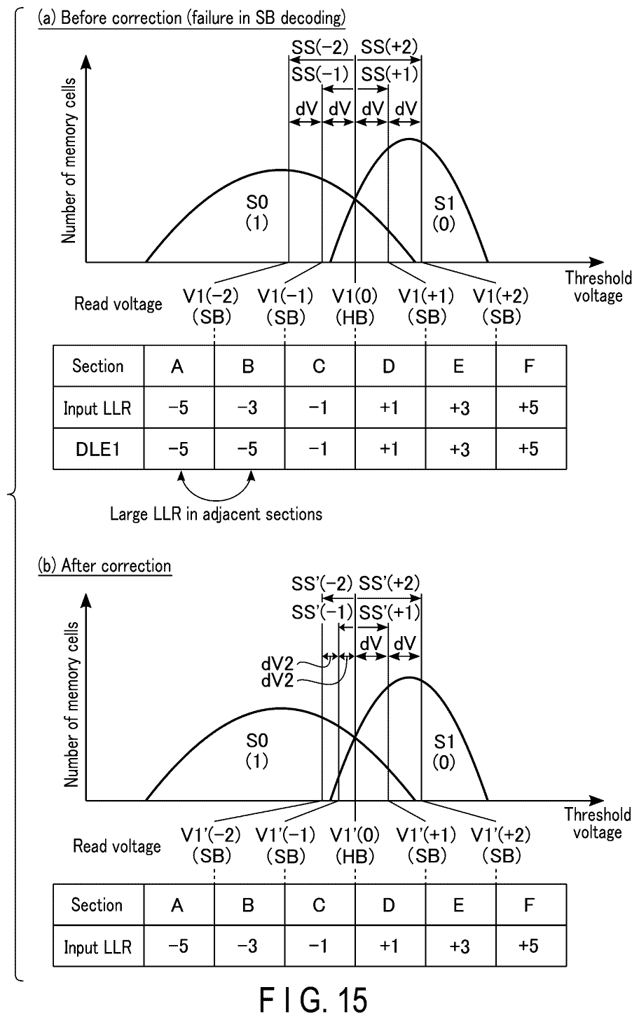

An example of a shift value correction process of a read voltage will be described with reference to FIGS. 14 and 15. FIG. 14 is a diagram illustrating an example of a shift value correction process to increase the interval between read voltages. FIG. 15 is a diagram illustrating an example of a shift value correction process to decrease the interval between read voltages. FIGS. 14(a) and 15(a) illustrate the relationships among threshold voltage distributions of the S0 state and the S1 state, the HB read voltage and the SB read voltages before correction (i.e., a state in which SB decoding has failed), an input LLR before correction, and DLE1. FIGS. 14(b) and 15(b) illustrate the relationships among the threshold voltage distributions of the S0 state and the S1 state, the HB read voltage and the SB read voltages after correction, and the input LLR after correction.

First, a case of widening the interval between read voltages will be described.

As illustrated in FIG. 14, the threshold voltage distribution of a certain state may have an asymmetric shape (non-normal distribution). In the example illustrated in FIG. 14(a), the skirt of the threshold voltage distribution of the S0 state is widened to the high voltage side. In these threshold voltage distributions, it is assumed that the hard bit decoding circuit 162 fails HB decoding, and the CPU 12 causes the sequencer 206 to execute SB reading.

As in the first embodiment described with reference to FIG. 6, the interval between read voltages is defined as dV. The read information generation circuit 17 sets −2dV, −dV, dV, and 2dV as SB shift values SS(−2), SS(−1), SS(+1), and SS(+2) with respect to the HB read voltage V1(0), respectively. If the soft bit decoding circuit 163 fails the SB decoding, the DLE calculation circuit 164 calculates DLE1 based on the failure data. In the example illustrated in FIG. 14(a), the values of DLE1 in the sections A, B, C, D, E, and F are −5, −3, −1, +1, +1, and +4. The values of DLE1 in the sections D and E adjacent to each other are both (+1). In this case, there is no increase in the amount of mutual information even the threshold voltage range is divided into the section D and the section E. In the example illustrated in FIG. 14(a), a position between the two sections in which the sign of the input LLR is inverted and a position between the two sections in which the sign of DLE1 is inverted are the same. In this case, the read information generation circuit 17 does not change the HB shift value. The post-correction HB read voltage V1′(0) is the same as the pre-correction HB read voltage V1(0) accordingly.

As illustrated in FIG. 14(b), the read information generation circuit 17 corrects the SB shift value based on the absolute value of DLE1 in each section, and adjusts the interval between read voltages. First, the read information generation circuit 17 searches for sections in which the absolute value of a difference between the values of DLE1 in two adjacent sections is smaller than a preset first determination value (for example, 1). In the example illustrated in FIG. 14(a), the values of DLE1 in the sections D and E adjacent to each other are both +1, and the absolute value of the difference is 0. Then, if the absolute values of DLE1 in the target sections (sections D and E) are smaller than a preset second determination value (for example, 3), the read information generation circuit 17 corrects the SB shift values corresponding to the target sections to widen the read voltage interval. For example, the absolute values of DLE1 in the sections D and E are 1, which is smaller than the second determination value. In this case, the read information generation circuit 17 widens the interval between the read voltages corresponding to the sections D and E. The widened interval between the read voltages is defined as dV1. The interval dV1 and the pre-correction interval dV have a relationship of dV1>dV. The read information generation circuit 17 sets dV1 and 2dV1 as the post-correction SB shift values SS′(+1) and SS′(+2), respectively. On the other hand, the read information generation circuit 17 does not change the SB shift values SS(−2) and SS(−1) on the low voltage side corresponding to the sections A, B, and C. The read information generation circuit 17 sets −2dV and −dV, which are the same as those before the correction, as the post-correction SB shift values SS′(−2) and SS′(−1), respectively. Therefore, the post-correction SB read voltages V1′(−2), V1′(−1), V1′(+1), and V1′(+2) can be expressed by the following formulas using the HB read voltage V1(0) and the SB shift values −2dV, −dV, dV1, and 2dV1, respectively.

$$V {1}^{′} ( - 2 ) = V {1}^{′} ( 0 ) + {SS}^{′} ( - 2 ) = V 1 ( 0 ) - 2 dV = V 1 ( - 2 ) \\ V {1}^{′} ( - 1 ) = V {1}^{′} ( 0 ) + {SS}^{′} ( - 1 ) = V 1 ( 0 ) - dV = V 1 ( - 1 ) \\ V {1}^{′} ( + 1 ) = V {1}^{′} ( 0 ) + {SS}^{′} ( + 1 ) = V 1 ( 0 ) + dV 1 \\ V {1}^{′} ( + 2 ) = V {1}^{′} ( 0 ) + {SS}^{′} ( + 2 ) = V 1 ( 0 ) + 2 dV 1$$

The post-correction SB read voltages V1′(−2) and V1′(−1) are the same as the pre-correction SB read voltages V1(−2) and V1(−1), respectively.

The number of SB read voltages on the low voltage side and the number of SB read voltages on the high voltage side with respect to the HB read voltage V1′(0) are the same as those before the correction. Therefore, the read information generation circuit 17 can use the same LLR as that before the correction as the input LLR.

Next, a case of narrowing the interval between read voltages will be described.

As illustrated in FIG. 15, the threshold voltage distributions of two adjacent states may have different widths. In the example illustrated in FIG. 15(a), the width of the threshold voltage distribution of the S0 state is larger than the width of the threshold voltage distribution of the S1 state. In these threshold voltage distributions, it is assumed that the hard bit decoding circuit 162 fails HB decoding, and the CPU 12 causes the sequencer 206 to execute SB reading.

As in the first embodiment described with reference to FIG. 6, the interval between read voltages is defined as dV. The read information generation circuit 17 sets −2dV, −dV, dV, and 2dV as SB shift values SS(−2), SS(−1), SS(+1), and SS(+2) with respect to the HB read voltage V1(0), respectively. If the soft bit decoding circuit 163 fails the SB decoding, the DLE calculation circuit 164 calculates DLE1 based on the failure data. In the example illustrated in FIG. 15(a), the values of DLE1 in the sections A, B, C, D, E, and F are −5, −5, −1, +1, +3, and +5. The values of DLE1 in the sections A and B adjacent to each other are both (−5). In this case, there is no increase in the amount of mutual information even the threshold voltage range is divided into the section A and the section B. In the example illustrated in FIG. 15(a), a position between the two sections in which the sign of the input LLR is inverted and a position between the two sections in which the sign of DLE1 is inverted are the same. In this case, the read information generation circuit 17 does not change the HB shift value. The post-correction HB read voltage V1′(0) is the same as the pre-correction HB read voltage V1(0) accordingly.

As illustrated in FIG. 15(b), the read information generation circuit 17 corrects the SB shift values based on the absolute value of DLE1 in each section, and adjusts the interval between read voltages. Similarly to the description with reference to FIG. 14, first, the read information generation circuit 17 searches for sections in which the absolute value of a difference between the values of DLE1 in two adjacent sections is smaller than the first determination value (for example, 1). In the example illustrated in FIG. 15(a), the values of DLE1 in the sections A and B adjacent to each other are both −5, and the absolute value of the difference is 0.

Then, if the absolute values of DLE1 in the target sections (sections A and B) are equal to or larger than the second determination value (for example, 3), the read information generation circuit 17 corrects the SB shift values corresponding to the target sections to narrow the read voltage interval. For example, the absolute values of DLE1 in the section A and section B are 5, which is equal to or larger than the second determination value. In this case, the read information generation circuit 17 narrows the interval between the read voltages corresponding to the sections A and B. The interval between the narrowed read voltages is defined as dV2. The interval dV2 and the pre-correction interval dV have a relationship of dV2<dV. The read information generation circuit 17 sets −2dV2 and −dV2 as the post-correction SB shift values SS′(−2) and SS′(−1), respectively. On the other hand, the read information generation circuit 17 does not change the SB shift values SS(+1) and SS(+2) on the high voltage side corresponding to the sections D, E, and F. The read information generation circuit 17 sets dV and 2dV, which are the same as those before the correction, as the post-correction SB shift values SS′(+1) and SS′(+2), respectively. Therefore, the post-correction SB read voltages V1′(−2), V1′(−1), V1′(+1), and V1′(+2) can be expressed by the following formulas using the HB read voltage V1(0) and the SB shift values −2dV2, −dV2, dV, and 2dV, respectively.

$$V {1}^{′} ( - 2 ) = V {1}^{′} ( 0 ) + {SS}^{′} ( - 2 ) = V 1 ( 0 ) - 2 dV 2 \\ V {1}^{′} ( - 1 ) = V {1}^{′} ( 0 ) + {SS}^{′} ( - 1 ) = V 1 ( 0 ) - dV 2 \\ V {1}^{′} ( + 1 ) = V {1}^{′} ( 0 ) + {SS}^{′} ( + 1 ) = V 1 ( 0 ) + dV = V 1 ( + 1 ) \\ V {1}^{′} ( + 2 ) = V {1}^{′} ( 0 ) + {SS}^{′} ( + 2 ) = V 1 ( 0 ) + 2 dV = V 1 ( + 2 )$$

The post-correction SB read voltages V1′(+1) and V1′(+2) are the same as the pre-correction SB read voltages V1(+1) and V1(+2), respectively.

The number of SB read voltages on the low voltage side and the number of SB read voltages on the high voltage side with respect to the HB read voltage V1′(0) are the same as those before the correction. Therefore, the read information generation circuit 17 can use the same LLR as that before the correction as the input LLR.

### 2.2 Procedure of Read Operation

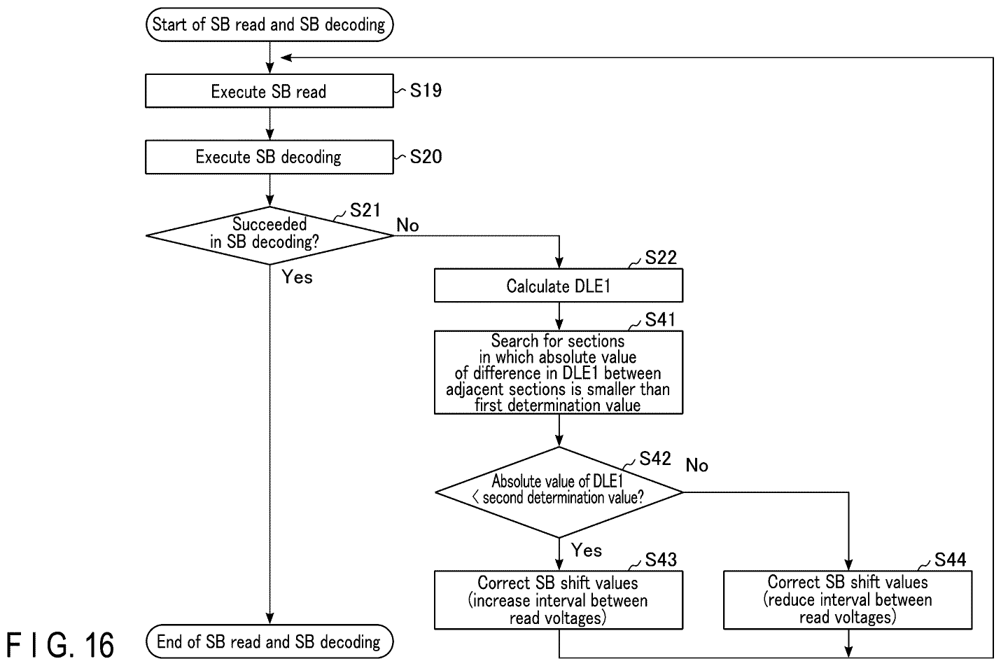

Next, an example of a procedure of a read operation will be described with reference to FIG. 16. FIG. 16 is a flowchart illustrating an example of a procedure of an SB read and SB decoding. FIG. 16 illustrates steps of the SB read and the SB decoding in the entire procedure of the read operation. In the entire procedure of the read operation, the steps of an HB read and HB decoding are similar to steps S10 to S18 in the first embodiment described with reference to FIG. 8.

As described in the first embodiment with reference to FIG. 8, if the HB decoding has failed (S18_No), the CPU 12 executes the SB read and the SB decoding.

As illustrated in FIG. 16, steps S19 to S22 are similar to those in the first embodiment described with reference to FIG. 9. If the soft bit decoding circuit 163 has succeeded in the SB decoding (S21_Yes), the CPU 12 ends the SB read and the SB decoding. That is, the CPU 12 transmits the error-corrected user data to the host 2 and ends the read operation.

If the soft bit decoding circuit 163 has failed in the SB decoding (S21_No), the DLE calculation circuit 164 calculates DLE1 using the failure data (S22). After the calculation of DLE1, the read information generation circuit 17 searches for sections in which the absolute value of a difference in DLE1 between two adjacent sections is smaller than the first determination value (S41). The read information generation circuit 17 compares a smaller value of the absolute values of DLE1 of the two sections detected by the search (alternatively, the absolute value of DLE1 of the two sections if they are equal) with the second determination value (S42).

If the absolute value of DLE1 to be compared is smaller than the second determination value (S42_Yes), the read information generation circuit 17 corrects the SB shift values corresponding to the target sections and widens (increases) the interval between the corresponding read voltages (S43).

If the absolute value of DLE1 to be compared is equal to or larger than the second determination value (S42_No), the read information generation circuit 17 corrects the SB shift values corresponding to the target sections and narrows (reduces) the interval between the corresponding read voltages (S44).

After correcting the SB shift values in step S43 or S44, the CPU 12 executes SB reading using the post-correction SB read voltages (S19). The CPU 12 may execute an additional read operation corresponding to the SB read voltages corrected as in step S24 of the first embodiment described with reference to FIG. 9, and proceed to step S20.

### 2.3 Effects of Present Embodiment

According to the configuration of the present embodiment, the memory system 3 can improve the reliability of data as in the first embodiment. Furthermore, according to the configuration of the present embodiment, the memory system 3 corrects the shift value based on DLE1. More specifically, the memory system 3 optimizes the intervals (threshold voltage ranges) between read voltages based on DLE1. That is, the memory system 3 can optimize the SB read voltages.

The present embodiment can be combined with the first embodiment, the first modification of the first embodiment, or the second modification of the first embodiment. That is, the memory system 3 may correct the HB shift value and the SB shift values based on the inverted position of the sign of DLE1 between two adjacent sections, and then adjust the interval between the SB read voltages (i.e., change the SB shift values) based on the absolute value of DLE1 in each section.

### 3. Third Embodiment

Next, a third embodiment will be described. In the third embodiment, an HB read voltage (an HB shift value) is calculated using a successful result of SB decoding. Hereinafter, differences from the first and second embodiments will be mainly described.

### 3.1 Configuration of Memory System

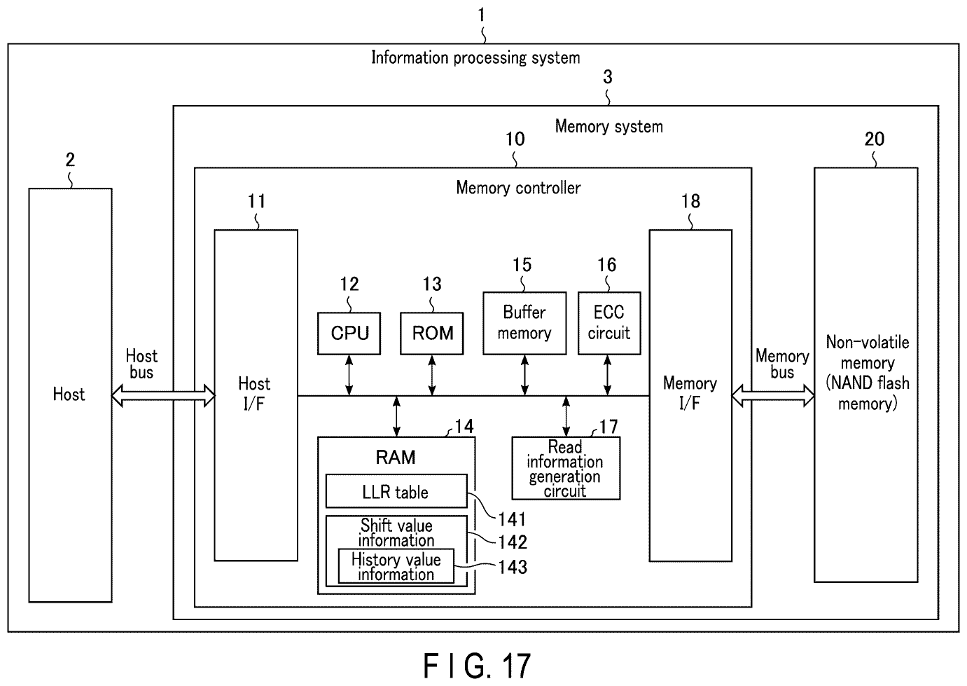

First, an example of a configuration of a memory system 3 will be described with reference to FIG. 17. FIG. 17 is a block diagram illustrating an overall configuration of an information processing system 1 including the memory system 3.

As illustrated in FIG. 17, the overall configuration of the information processing system 1 is similar to that of the first embodiment described with reference to FIG. 1.

As illustrated in FIG. 17, the configuration of a memory controller 10 is similar to that of the first embodiment described with reference to FIG. 1, except for information stored in a RAM 14.

The RAM 14 stores an LLR table 141 and shift value information 142, for example.

The shift value information 142 of the present embodiment includes history value information 143. In other words, the RAM 14 stores the history value information 143. The history value information 143 is information of a shift value (hereinafter, also referred to as history value) of the read voltage generated based on successful results of SB decoding. In the present embodiment, the history value (the HB shift value) corresponding to an HB read voltage is stored. For example, in the HB read, a CPU 12 transmits a Set Feature related to the history value and a command set of the HB read to a NAND flash memory 20. A sequencer 206 sets the HB read voltage based on the history value of the HB shift value designated by the Set Feature.

For example, if an ECC circuit 16 has succeeded in the SB decoding, a read information generation circuit 17 of the present embodiment generates the history value of the HB read voltage based on the successful result (success data) of the SB decoding. More specifically, if a soft bit decoding circuit 163 has succeeded in the SB decoding, a DLE calculation circuit 164 of the present embodiment generates a channel matrix using the success data. The DLE calculation circuit 164 calculates DLE2 using the channel matrix based on the success data. The read information generation circuit 17 generates the history value based on DLE2.

### 3.2 Procedure of Read Operation

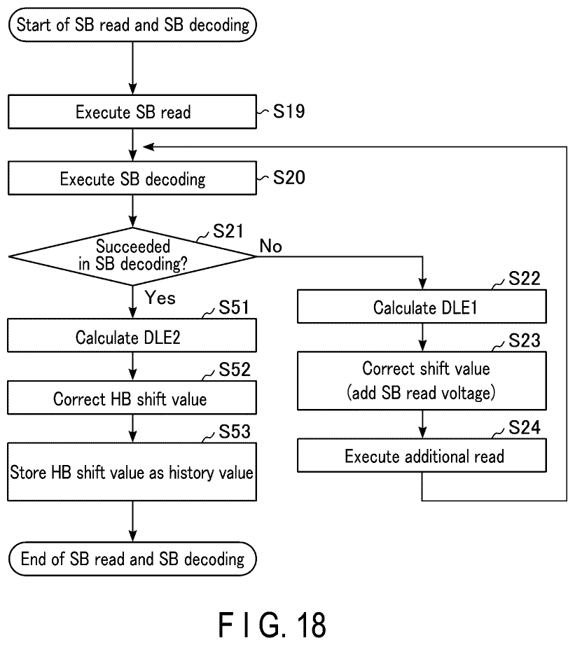

An example of a procedure of a read operation will be described with reference to FIG. 18. FIG. 18 is a flowchart illustrating an example of steps of an SB read and SB decoding. FIG. 18 illustrates steps of the SB read and the SB decoding in the entire procedure of the read operation. In the entire procedure of the read operation, the steps of an HB read and HB decoding are similar to steps S10 to S18 in the first embodiment described with reference to FIG. 8.

As described in the first embodiment with reference to FIG. 8, if the HB decoding has failed (S18_No), the CPU 12 executes the SB read and the SB decoding.

As illustrated in FIG. 18, steps S19 and S20 are similar to those in the first embodiment described with reference to FIG. 9.

If the soft bit decoding circuit 163 has failed in the SB decoding (S21_No), the CPU 12 sequentially executes steps S22 to S24 as in the first embodiment described with reference to FIG. 9.

If the soft bit decoding circuit 163 has succeeded in the SB decoding (S21_Yes), the DLE calculation circuit 164 calculates DLE2 using the success data of the SB decoding (S51). For example, the DLE calculation circuit 164 generates a channel matrix using the success data as in the first embodiment. Then, the DLE calculation circuit 164 calculates the DLE2 using the channel matrix of the success data.

The read information generation circuit 17 corrects the HB shift value based on the DLE2 (S52). In other words, the read information generation circuit 17 generates a history value corresponding to the HB read voltage based on the DLE2. For example, the read information generation circuit 17 sets the HB read voltage at a position between two sections where the sign of the DEL2 is inverted as in the first embodiment. In other words, the read information generation circuit 17 corrects the HB shift value such that the HB read voltage is set at the position between the two sections where the sign of the DEL2 is inverted (that is, a history value is generated).

The read information generation circuit 17 stores the corrected HB shift value in the RAM 14 as the history value of the HB read voltage (S53).

### 3.3 Effects of Present Embodiment

According to the configuration in the present embodiment, the same effects as those of the first embodiment can be obtained.

Furthermore, according to the configuration in the present embodiment, the memory system 3 calculates DLE2 using the success data of successful SB decoding. Then, the memory system 3 generates a history value of the HB read voltage based on the DLE2. The success rate of the HB decoding and the SB decoding can be improved by using the history value in the HB read after the generation of the history value. Therefore, it is possible to improve data reliability.

Furthermore, according to the configuration in the present embodiment, since the memory system 3 can improve the success rate of the HB decoding and the SB decoding, it is possible to suppress an increase in the latency of the read operation.

The present embodiment can be combined with the first embodiment, the first modification of the first embodiment, the second modification of the first embodiment, or the second embodiment.

### 3.4 Modification of Third Embodiment

Next, a modification of the third embodiment will be described. In the present modification, a history value of an SB read voltage is generated. Hereinafter, differences from the third embodiment will be mainly described.

### 3.4.1 Procedure of Read Operation

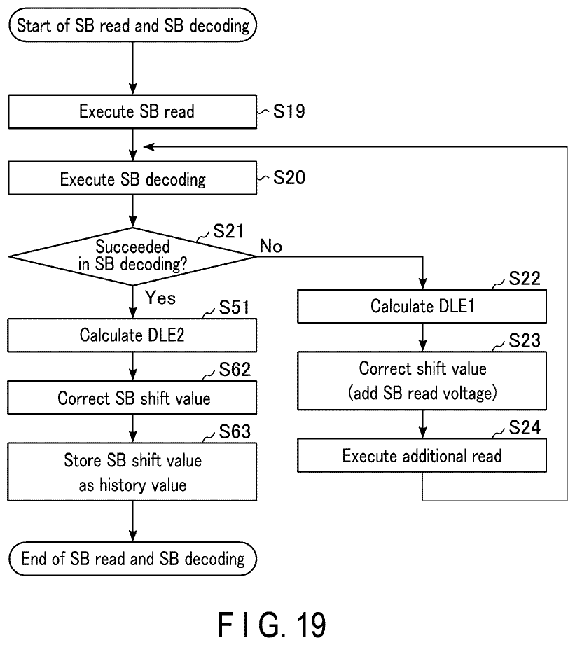

An example of a procedure of a read operation will be described with reference to FIG. 19. FIG. 19 is a flowchart illustrating an example of a procedure of an SB read and SB decoding. FIG. 19 illustrates steps of the SB read and the SB decoding in the entire procedure of the read operation. In the entire procedure of the read operation, the steps of an HB read and HB decoding are similar to steps S10 to S18 in the first embodiment described with reference to FIG. 8.

As described in the first embodiment with reference to FIG. 8, if the HB decoding has failed (S18_No), the CPU 12 executes the SB read and the SB decoding.

As illustrated in FIG. 19, steps S19 and S20 are similar to those in the first embodiment described with reference to FIG. 9.

If the soft bit decoding circuit 163 has failed in the SB decoding (S21_No), the CPU 12 sequentially executes steps S22 to S24 as in the first embodiment described with reference to FIG. 9.

If the soft bit decoding circuit 163 has succeeded in the SB decoding (S21_Yes), the DLE calculation circuit 164 calculates DLE2 using the success data of the SB decoding (S51).

The read information generation circuit 17 corrects the SB shift values based on the DLE2 (S62). In other words, the read information generation circuit 17 generates history values corresponding to SB read voltages based on the DLE2. For example, the read information generation circuit 17 corrects the SB shift values based on the absolute value of the DLE2 in each section to adjust the interval between read voltages as in the second embodiment. The read information generation circuit 17 may correct the HB shift value and the SB shift values based on DLE2 as in the first embodiment.

The read information generation circuit 17 stores the corrected SB shift values in the RAM 14 as history values of the SB read voltages (S63). If the HB shift value and the SB shift values were corrected based on the DLE2, the read information generation circuit 17 may store the corrected HB shift value and SB shift values in the RAM 14 as history values.

For example, in the SB read after the generation of the history values, the CPU 12 transmits a Set Feature related to the history values of the SB read voltages and a command set of the SB read to the NAND flash memory 20. The sequencer 206 sets the SB read voltages based on the history values of the SB shift values designated by the Set Feature.

### 3.4.2 Effects of Present Modification

According to the configuration of the present modification, the memory system 3 can achieve the same effects as those of the first embodiment.

Furthermore, according to the configuration in the present modification, the memory system 3 calculates DLE2 using the success data of successful SB decoding. Then, the memory system 3 generates history values of the SB read voltages based on the DLE2. The success rate of the SB decoding can be improved by using the history values in the SB read after the generation of the history values. Therefore, it is possible to improve data reliability.

Furthermore, according to the configuration in the present modification, since the memory system 3 can improve the success rate of the SB decoding, it is possible to suppress an increase in the latency of the read operation.

The present modification can be combined with the first embodiment, the first modification of the first embodiment, the second modification of the first embodiment, or the second embodiment.

### 4. Modifications and Others

A memory system according to the above embodiments comprises a non-volatile memory (20) and a memory controller (10). The non-volatile memory includes a plurality of memory cells (MC) each configured to store data according to a threshold voltage. The memory controller is configured to set a first read voltage (HB read voltage) based on a first shift value (HB shift value), acquire hard bit data (HB data) from the plurality of memory cells by a first read operation (HB read) using the first read voltage, set a second read voltage (SB read voltage) based on a second shift value (SB shift value), acquire soft bit data (SB data) from the plurality of memory cells by a second read operation (SB read) using the second read voltage, execute first error correction (SB decoding) on data read from the plurality of memory cells by using the hard bit data and the soft bit data, calculate a first log likelihood ratio (DLE1) by using at least a result of the first error correction that has failed (failure data) when the first error correction has failed, and correct at least one of the first shift value and the second shift value based on the first log likelihood ratio.

According to the configurations of the above embodiments, the memory system can improve the reliability of data.

The present invention is not limited to the above-described embodiments, and can be applied to various modifications.

The term coupling in the above embodiments also includes a state of being indirectly coupled with a transistor or a resistor interposed in between, for example.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory system comprising:
a non-volatile memory that includes a plurality of memory cells each configured to store data according to a threshold voltage; and
a memory controller configured to:
set a first read voltage based on a first shift value;
acquire hard bit data from the plurality of memory cells by a first read operation using the first read voltage;
set a second read voltage based on a second shift value;
acquire soft bit data from the plurality of memory cells by a second read operation using the second read voltage;
execute first error correction on data read from the plurality of memory cells by using the hard bit data and the soft bit data;
in a case where the first error correction has failed, calculate a first log likelihood ratio (LLR) by using at least a result of the first error correction that has failed; and
correct at least one of the first shift value and the second shift value based on the first LLR.

2. The memory system according to claim 1, wherein
the memory controller is further configured to:
manage a plurality of sections each of which is obtained by dividing a range of the threshold voltage;
in the case where the first error correction has failed, calculate the first LLR for each of the plurality of sections; and
correct the first shift value such that the first read voltage is set between a first section and a second section, the first section is one of the plurality of sections and the first LLR having a negative value was calculated for the first section, and the second section is another one of the plurality of sections adjacent to the first section and the first LLR having a positive value was calculated for the second section.

3. The memory system according to claim 2, wherein
the memory controller is further configured to:
determine a third read voltage for use in the second read operation, in response to the correction of the first shift value; and
cause the non-volatile memory to execute a third read operation using the third read voltage.

4. The memory system according to claim 3, wherein the memory controller is further configured to, in a case where the first read voltage based on the first shift value that is corrected is lower than the first read voltage based on the first shift value before the correction, set the third read voltage to be lower than the first read voltage based on the first shift value that is corrected.

5. The memory system according to claim 2, wherein
the memory controller is further configured to:
replace the second read voltage for use in the second read operation with a third read voltage different from the second read voltage, in response to the correction of the first shift value; and
cause the non-volatile memory to execute a third read operation using the third read voltage.

6. The memory system according to claim 5, wherein the memory controller is further configured to replace the second read voltage that is higher than the first read voltage, with the third read voltage that is lower than the first read voltage.

7. The memory system according to claim 2, wherein
the memory controller is further configured to:
execute the second read operation using at least the second read voltage and a third read voltage different from the second read voltage;
replace the second read voltage with a fourth read voltage different from the second read voltage, in response to the correction of the first shift value; and
cause the non-volatile memory to execute a fourth read operation using at least the third read voltage and the fourth read voltage.

8. The memory system according to claim 7, wherein the memory controller is further configured to replace the second read voltage that is higher than the first read voltage, with the fourth read voltage that is lower than the first read voltage.

9. The memory system according to claim 2, wherein
the memory controller is further configured to:
for each of the plurality of sections, count the number of memory cells whose threshold voltage belongs to the each of the plurality of sections, using a result of the first error correction; and
calculate the first LLR based on a result of the counting.

10. The memory system according to claim 1, wherein the second read voltage is obtained by adding the second shift value to the first read voltage.

11. The memory system according to claim 1, wherein
the memory controller is further configured to:
manage a plurality of sections each of which is obtained by dividing a range of the threshold voltage;
in the case where the first error correction has failed, calculate the first LLR for each of the plurality of sections;
search the plurality of sections for a first section and a second section that is adjacent to the first section, an absolute value of a difference between the first LLR in the first section and the first LLR in the second section being smaller than a first determination value; and
in a case where a smaller value of an absolute value of the first LLR in the first section and an absolute value of the first LLR in the second section is smaller than a second determination value, correct the second shift value used to set the second read voltage corresponding to the first section, and correct a third shift value used to set a third read voltage corresponding to the second section, such that a range of the threshold voltage corresponding to the first section and a range of the threshold voltage corresponding to the second section are widened.

12. The memory system according to claim 11, wherein the memory controller is further configured to, in a case where the smaller value of the absolute values of the first LLRs in the first and second sections is equal to or larger than the second determination value, correct the second shift value and the third shift value such that the range of the threshold voltage corresponding to each of the first and second sections is narrowed.

13. The memory system according to claim 1, wherein
the memory controller is further configured to:
in a case where the first error correction has succeeded, calculate a second LLR by using at least a result of the first error correction that has succeeded; and
correct at least one of the first shift value and the second shift value based on the second LLR.

14. The memory system according to claim 1, wherein the memory controller is further configured to, in a case where second error correction different from the first error correction using the hard bit data has failed, execute the second read operation and execute the first error correction.

15. The memory system according to claim 1, wherein
the memory controller is further configured to:
execute the first error correction using the hard bit data, the soft bit data, and a preset third LLR; and
update the third LLR based on the first LLR.

16. A method of controlling a non-volatile memory that includes a plurality of memory cells each configured to store data according to a threshold voltage, the method comprising:
setting a first read voltage based on a first shift value;
acquiring hard bit data from the plurality of memory cells by a first read operation using the first read voltage;
setting a second read voltage based on a second shift value;
acquiring soft bit data from the plurality of memory cells by a second read operation using the second read voltage;
executing first error correction on data read from the plurality of memory cells by using the hard bit data and the soft bit data;
determining that the first error correction has failed;
in response to determining that the first error correction has failed, calculating a first log likelihood ratio (LLR) by using at least a result of the first error correction that has failed; and
correcting at least one of the first shift value and the second shift value based on the first LLR.

17. The method according to claim 16, further comprising:
managing a plurality of sections each of which is obtained by dividing a range of the threshold voltage;
in response to determining that the first error correction has failed, calculating the first LLR for each of the plurality of sections;
determining a first section that is one of the plurality of sections and the first LLR having a negative value was calculated for the first section;
determining a second section that is another one of the plurality of sections adjacent to the first section and the first LLR having a positive value was calculated for the second section; and
correcting the first shift value such that the first read voltage is set between the first section and the second section.

18. The method according to claim 16, wherein the second read voltage is obtained by adding the second shift value to the first read voltage.

19. The method according to claim 16, further comprising:
managing a plurality of sections each of which is obtained by dividing a range of the threshold voltage;
in response to determining that the first error correction has failed, calculating the first LLR for each of the plurality of sections;
searching the plurality of sections for a first section and a second section that is adjacent to the first section, an absolute value of a difference between the first LLR in the first section and the first LLR in the second section being smaller than a first determination value;
determining that a smaller value of an absolute value of the first LLR in the first section and an absolute value of the first LLR in the second section is smaller than a second determination value; and
in response to determining that the smaller value is smaller than the second determination value, correcting the second shift value used to set the second read voltage corresponding to the first section, and correcting a third shift value used to set a third read voltage corresponding to the second section, such that a range of the threshold voltage corresponding to the first section and a range of the threshold voltage corresponding to the second section are widened.

20. The method according to claim 16, further comprising:
determining that the first error correction has succeeded;
in response to determining that the first error correction has succeeded, calculating a second LLR by using at least a result of the first error correction that has succeeded; and
correcting at least one of the first shift value and the second shift value based on the second LLR.
